(19) United States
(12) Patent Application Publication
(10) Pub. No.: US 2026/0180531 A1
(43) Pub. Date: Jun. 25, 2026

(54) Circuit having Multiple Cascode Amplifiers and Controllable Components

(71) Applicant: TEXAS INSTRUMENTS INCORPORATED, Dallas, TX (US)

(72) Inventors: Ashlesha Yerramsetty, Hyderabad (IN); Radhika Juluri, Bangalore (IN); Meghna Agrawal, Bengaluru (IN); Debapriya Sahu, Bangalore (IN); Srinivas Veeramreddi, Bengaluru (IN); Prakhar Agrawal, Bangalore (IN)

(21) Appl. No.: 19/071,689

(22) Filed: Mar. 5, 2025

(30) Foreign Application Priority Data
Dec. 20, 2024 (IN) 202441101249

(51) Int. Cl. H03F 3/45

(52) U.S. Cl. CPC H03F 3/45269; H03F 2200/294; H03F 2200/451

(57) ABSTRACT

A system includes a radio frequency (RF) receiver having a low noise trans-impedance amplifier (LNTA). The LNTA is configured to receive a single-ended RF voltage signal and convert the RF voltage signal to a differential current mode signal. The LNTA is configured for adjustable gain by controllable circuits.

### CROSS-REFERENCE TO RELATED APPLICATIONS

The present application claims the benefit of Indian Provisional Patent Application 20/244,1101249, filed Dec. 20, 2024, the disclosure of which is hereby incorporated by reference in its entirety.

### TECHNICAL FIELD

The present application relates to electronic circuits, and in particular embodiments, to circuits having multiple cascode amplifiers and controllable components.

### BACKGROUND

Radio frequency (RF) receivers are used in a variety of devices that rely on wireless communications. These RF receivers may operate at a variety of frequencies based on their applications. For example, cellular telephones, Wi-Fi devices, Bluetooth devices, and the like, operate at a variety of frequencies and may employ a RF transmitters to receive signals over the air.

### SUMMARY

In accordance with an embodiment, an electronic circuit including: first and second output terminals; an input terminal; a first cascode amplifier having first and second control terminals and first and second current path terminals, where the first control terminal of the first cascode amplifier is coupled to the input terminal, and where the second current path terminal of the first cascode amplifier is coupled to the first output terminal; a second cascode amplifier having first and second control terminals and first and second current path terminals, where the first control terminal of the second cascode amplifier is coupled to the first current path terminal of the first cascode amplifier via a first capacitor; a third cascode amplifier having first and second control terminals and first and second current path terminals, where the second current path terminal of the third cascode amplifier is coupled to the first output terminal, and where the second current path terminal of the third cascode amplifier is coupled to the second output terminal; a fourth cascode amplifier having first and second control terminals and first and second current path terminals, where the first control terminal of the fourth cascode amplifier is coupled to the first current path terminal of the third cascode amplifier via a second capacitor, and where the second current path terminal of the fourth cascode amplifier is coupled to the second output terminal; and a controllable circuit including: a quantity (N) of first components, each first component having a first transistor arranged between the first current path terminal of the first cascode amplifier and the second current path terminal of the first cascode amplifier and a second transistor arranged between the first current path terminal of the third cascode amplifier and the second current path terminal of the third cascode amplifier, where N is an integer equal to or greater than 1, and a quantity (M) of second components, each second component having a first transistor coupled to the first current path terminal of the first cascode amplifier, and a second transistor coupled to the first current path terminal of the third cascode amplifier, where M is an integer greater than 1.

In accordance with an embodiment, an electronic circuit including: a first cascode amplifier having an output terminal; a second cascode amplifier having an output terminal, a third cascode amplifier having an output terminal, where the output terminal of the first cascode amplifier is coupled to the output terminal of the third cascode amplifier; a fourth cascode amplifier having an output terminal, where the output terminal of the fourth cascode amplifier is coupled to the output terminal of the second cascode amplifier; a first controllable circuit coupled to the first and third cascode amplifiers and configured to adjust a first amount of current at the output terminal of the first cascode amplifier; a second controllable circuit coupled to the second and fourth cascode amplifiers and configured to adjust a second amount of current at the output terminal of the second cascode amplifier; and a gain control circuit coupled to the first controllable circuit and to the second controllable circuit, the gain control circuit configured to adjust a gain at the output terminals of the first cascode amplifier, the second cascode amplifier, the third cascode amplifier, and the fourth cascode amplifier by applying control signals to the first controllable circuit and to the second controllable circuit.

In accordance with an embodiment, a device including: a low noise trans-impedance amplifier (LNTA) including: a first cascode amplifier having an output terminal; a second cascode amplifier having an output terminal, a third cascode amplifier having an output terminal, where the output terminal of the first cascode amplifier is coupled to the output terminal of the third cascode amplifier; a fourth cascode amplifier having an output terminal, where the output terminal of the fourth cascode amplifier is coupled to the output terminal of the second cascode amplifier; a first controllable circuit coupled to the first and third cascode amplifiers and configured to adjust a first amount of current at the output terminal of the first cascode amplifier; and a second controllable circuit coupled to the second and fourth cascode amplifiers and configured to adjust a second amount of current at the output terminal of the second cascode amplifier; and a gain control circuit, coupled to the first controllable circuit and to the second controllable circuit, and configured to affect a gain of the LNTA by applying control signals to the first controllable circuit and to the second controllable circuit.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an illustration of an example system for receiving and transmitting radio frequency (RF) signals, according to some embodiments;

FIG. 2 is an illustration of an example system for receiving RF signals, according to some embodiments; and

FIG. 3 is an illustration of an an example low noise trans-impedance amplifier (LNTA), for use in the example embodiments of FIG. 1 and FIG. 2;

FIG. 4 is an illustration of an example LNTA for use in the example embodiments of FIG. 1 and FIG. 2, according to some embodiments;

FIGS. 5-6 are an illustration of an example architecture for parallel switches, according to some embodiments;

FIG. 7 is an illustration of an example architecture for bleeders, according to some embodiments;

FIG. 8 is an illustration of a multitude of gain steps, which may be implemented by a receive AGC circuit, to provide a multitude of gain steps for operation of example LNTAs, according to some embodiments;

FIGS. 9-10 are an illustration of an example architecture for bleeders, according to some embodiments;

FIGS. 11-12 are an illustration of example bias circuits for bleeders, according to some embodiments;

FIG. 13 is an illustration of an example LNTA for use in the example embodiments of FIG. 1 and FIG. 2, according to some embodiments;

FIGS. 14-15 are an illustration of an example architecture for bleeders, according to some embodiments;

FIG. 16 is an illustration of an example LNTA for use in the example embodiments of FIG. 1 and FIG. 2, according to some embodiments;

FIGS. 17-18 are an illustration of an example architecture for bleeders, according to some embodiments;

FIG. 19 is an illustration of example gain steps for use in the example implementations of FIGS. 16-18, according to some embodiments;

FIG. 20 is an illustration of an example bias circuit, for use with example LNTAs, according to some embodiments; and

FIG. 21 is an illustration of an example receive AGC circuit, to implement variable gain in receivers, according to some embodiments.

Corresponding numerals and symbols in different figures. generally refer to corresponding parts unless otherwise indicated. The figures are drawn to clearly illustrate the relevant aspects of the preferred embodiments and are not necessarily drawn to scale.

### DETAILED DESCRIPTION

The present disclosure is described with reference to the attached figures. The figures are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

The description below illustrates various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Various embodiments provide circuits using a low noise trans-impedance amplifier (LNTA) to provide differential current mode signals based on input single-ended radio frequency (RF) signals. An example architecture for use in an LNTA, according to some embodiments, uses four cascode amplifier circuits. A first cascode amplifier circuit may include two P type metal oxide semiconductor (PMOS) transistors, where a first PMOS transistor has a gate and a set of current path terminals (e.g., a source and a drain). The source of the first PMOS transistor may be coupled to a first polarity power supply (e.g., VDD), its drain may be coupled to the source of a second PMOS transistor, and its gate may be coupled to an RF input via a capacitor.

The first cascode amplifier may be coupled to a second cascode amplifier, where that second cascode amplifier is coupled to a second polarity power supply (e.g., ground). The second cascode amplifier may include two N type metal oxide semiconductor (NMOS) transistors. A first NMOS transistor has a gate and current path terminals such as a source and a drain. The source of the first NMOS transistor may be coupled to ground, the drain may be coupled to a second NMOS transistor, and the gate may be coupled to the RF input. A second NMOS transistor of the second cascode amplifier may have its source coupled to the drain of the first NMOS transistor, and its drain coupled to the drain of the second PMOS transistor, and its gate coupled to a bias voltage.

A third cascode amplifier may be implemented similarly to the first cascode amplifier so that it has two PMOS transistors. However, the gate of the first PMOS transistor of the third cascode amplifier is coupled to the drain of the first PMOS transistor of the first cascode amplifier. A fourth cascode amplifier may be implemented similarly to the second cascode amplifier, having two NMOS transistors. In the case of the fourth cascode amplifier, the gate of the first NMOS transistor is coupled to the drain of the first NMOS transistor of the second cascode amplifier.

Further in this example, LNTA may be configured so that the first NMOS transistor of the second cascode amplifier has a polarity-shifted relationship between its drain and its gate. As noted above, the drain of the first NMOS transistor of the second cascode amplifier may be coupled to the gate of the first NMOS transistor of the fourth cascode amplifier. This results in a relationship in which a gain from gate to source is negative one. This relationship may result in the first and second cascode amplifiers providing a positive output, and the third and fourth cascode amplifiers providing a negative output. The positive and negative outputs in this example are a current mode differential output.

Various embodiments include controllable components to the LNTA. For instance, the side of the LNTA that produces the positive output may include a set of parallel switches and a set of bleeders, and the side of the LNTA that produces the negative output may also include a similar set of parallel switches and a similar set of bleeders. The parallel switches and bleeders may include transistors that are configured to receive control signals from an adjustable gain control circuit. The adjustable gain control circuit may control the transistors to cause some current paths in the parallel switches and in the bleeders to turn on or off, thereby controlling a gain of the LNTA.

Various embodiments may include potential advantages versus other systems. For instance, embodiments using the sets of parallel switches and sets of bleeders may add further tuning capability, thereby allowing for an automatic gain control algorithm to avoid saturation of a receive signal chain.

Furthermore, systems using an LNA rather than an LNTA may implement a tank circuit at the output of the LNA. However, systems using the above-described example LNTA may omit the use of the tank circuit, thereby advantageously reducing an amount of materials and semiconductor area for the system.

Furthermore, various embodiments may omit use of a transformer at the output of the LNTA. Use of a transformer at the output would generally be expected to cause gain loss. By contrast, various embodiments may advantageously avoid such a gain loss.

Additionally, various embodiments implement the LNTA having a differential output. The differential output may allow for use of a 50% duty cycle mixer. A combination of a differential output and a 50% duty cycle mixer may advantageously result in less second-order intermodulation distortion than would be expected in a system using a single-ended output and a 25% duty cycle mixer.

Also, various embodiments may use capacitive matching for the RF input to the example LNTA. By contrast, other systems may use inductive matching. Various embodiments using capacitive matching may advantageously save materials and semiconductor area versus systems using inductive matching.

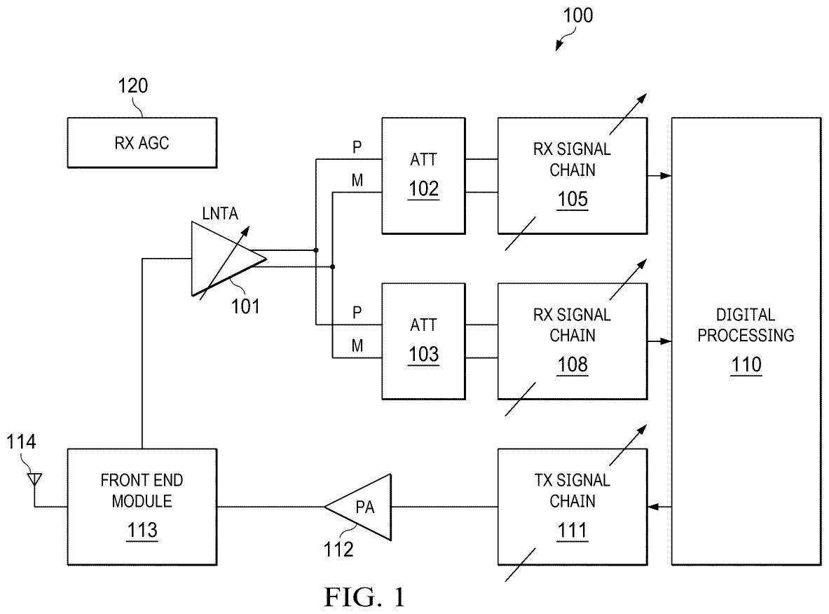

FIG. 1 is an illustration of an example system 100, according to some embodiments. In this example, system 100 may be implemented as a transceiver, which may be used for receiving and transmitting RF signals.

LNTA 101 may receive single-ended RF signals (e.g., wireless networking signals) from front-end module 113 and antenna 114. For instance, the receive signal chains 105, 108, may share the front-end module 113 and the antenna 114 with the transmit signal chain 111. The front end module 113 may include, e.g., filters and switches so that antenna 114 may be used for both transmitting and receiving over the air. For instance, the front end module 113 may include switches to perform a multiplexing function over time so that at some times antenna 114 is used for reception and other times antenna 114 is used for transmission. Front end module 113 may also include filters to remove unwanted signals. However, the scope of implementations is not limited to LNTA 101 sharing antenna 114 with power amplifier 112. Rather, the scope of implementations may include power amplifier 112 having its own antenna or antenna array separate from an antenna or antenna array used for LNTA 101.

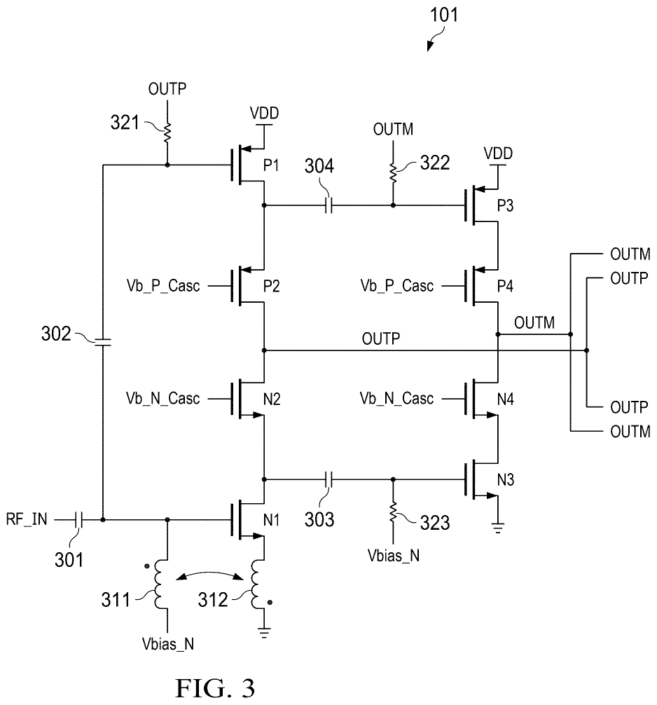

In some embodiments, LNTA 101 includes one or more sets of differential outputs, which are coupled to receive signal chain 105 (via attenuator 102) and coupled to receive signal chain 108 (via attenuator 103). In an example, a first set of differential outputs is coupled to attenuator 102, and a second set of differential outputs is coupled to attenuator 103. In another example, a single set of differential outputs is coupled to both attenuator 102 and attenuator 103. In these examples, the positive (+) conductor of each differential output is labeled with P, and the negative (−) conductor of each differential output is labeled M. Furthermore, the output of LNTA 101 is a current mode signal. Example architectures that may be used for LNTA 101 is described in more detail with respect to FIGS. 3, 4, 13, and 16.

In some embodiments, The attenuators 102 and 103 may be implemented in any appropriate manner. For instance, each one of attenuators 102 and 103 may be implemented as adjustable capacitive attenuator circuits, such as those described in United States Patent Application entitled, “CIRCUITS AND METHODS PROVIDING A SIGNAL PATH WITH AN ADJUSTABLE ATTENUATOR,” associated with attorney number T105315US01, filed on even date herewith and incorporated by reference herein. Nevertheless, other attenuators, such as resistive attenuators may be used in other embodiments. Furthermore, some embodiments may dispense with attenuators 102 and 103 altogether, instead relying upon adjustable gain components within the receive signal chains 105 and 108.

System 100 includes both receive signal chain 105 and receive signal chain 108. In one example, receive signal chain 105 is associated with an in-phase (I) signal, and receive signal chain 108 is associated with a quadrature-phase (Q) signal. Both of the RX signal chains 105 and 108 may include components that have adjustable gains. Examples of components in RX signal chains 105 and 108 may include mixers, filters, amplifiers, and/or other appropriate components. Thus, in some examples, each receive signal chain 105, 108 may include a mixer to reduce a frequency of the signal down to baseband or intermediate frequency, one or more filters and amplifiers to adjust a gain, and an analog-to-digital converter (ADC) circuit. At the output of each receive signal chain 105, 108, is a digital signal, which may be received by digital processing circuit 110. Examples of digital processing components may include processors, memory, and other digital circuits, which allow for processing data and for controlling operation of system 100.

In some embodiments, transmit signal chain 111 is also coupled to digital processing circuit 110, and it may receive digital signals, which it may convert to analog signals to transmit as RF signals over antenna 114. For instance, the transmit signal chain 111 may include a digital to analog converter (DAC) circuit, amplifiers, filters, a mixer, and/or the like. One or multiple components within transmit signal chain 111 may include variable gain. Transmit signal chain 111 may provide an RF signal to the power amplifier 112. The power amplifier 112 may amplify the RF signal to an appropriate level for transmission over a wireless medium by antenna 114.

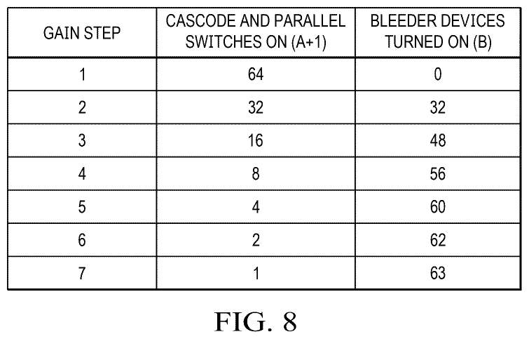

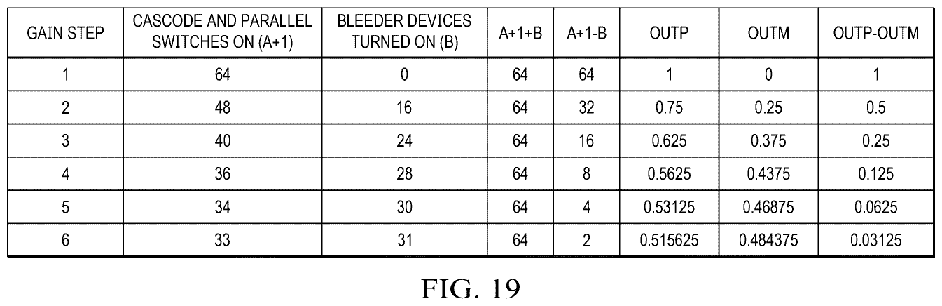

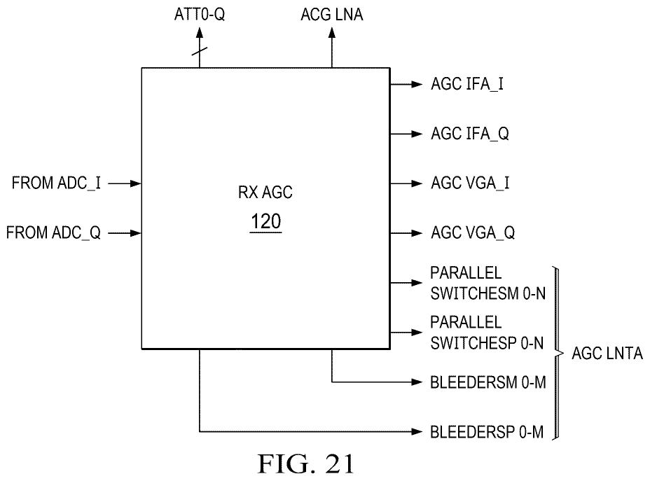

Receive AGC circuit 120 may control adjustable gain in any of the receive components, such as in the LNTA 101, attenuators 102 and 103, and receive signal chains 105 and 108. An example AGC algorithm, such as may be implemented by receive AGC circuit 120, is described in more detail in United States Patent Application entitled, “CIRCUITS AND METHODS PROVIDING A SIGNAL PATH WITH AN ADJUSTABLE ATTENUATOR,” associated with attorney number T105315US01, an example AGC gain steps are described in more detail with respect to FIGS. 8 and 19. An example receive AGC circuit, which may be used as receive AGC circuit 120, is described in more detail with respect to FIG. 21.

System 100 may be implemented on one or more chips. Each of the chips may be implemented using semiconductor dies in semiconductor packaging. In one example, the entirety of system 100 may be implemented on a single integrated circuit (IC) chip. In another example, some parts of system 100, such as antenna 114, may be either on a separate chip or not on a chip at all. In another example, LNTA 101, PA 112, front end module 113, and antenna 114 may be implemented separately from a chip on which the receive signal chains 105 and 108, the transmit signal chain 111, and the digital processing 110 are implemented. In yet another example, system 100 may be implemented as part of a larger system-on-a-chip, having other circuits, such as a modem, processor cores, and the like.

System 100 may be used in any appropriate application, such as in a Wi-Fi access point, a smart phone, a Bluetooth device, a Bluetooth low energy (BLE) device, an ultra-wideband (UWB) device, a radar device, and/or the like.

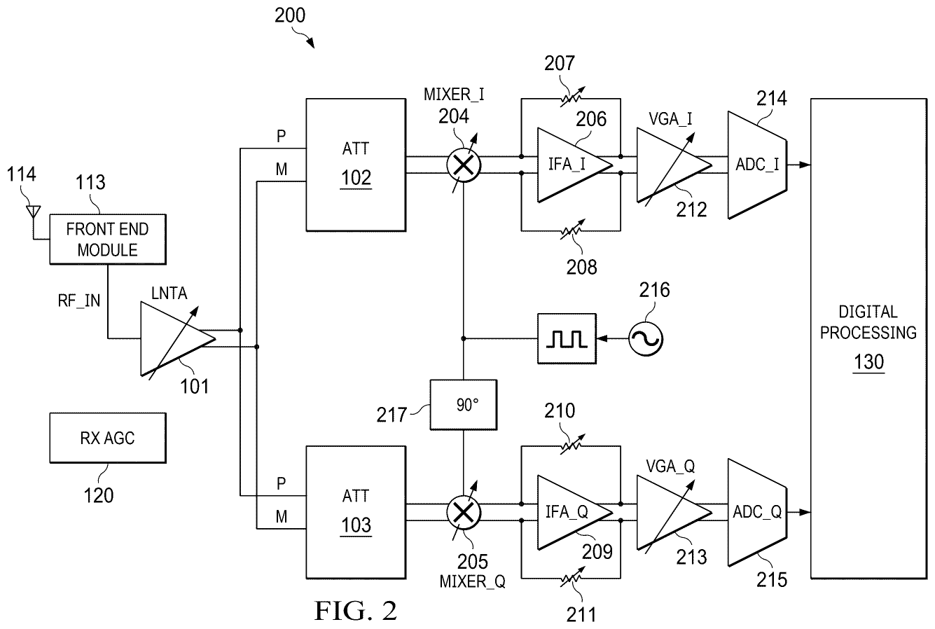

FIG. 2 is an illustration of an example system 200, for receiving wireless signals, according to some embodiments. For ease of illustration, a transmit signal chain has not been illustrated in FIG. 2, though it is understood that system 200 may be implemented with a transmit signal chain coupled to the front end module 113.

Example system 200 may be implemented according to the principles discussed above with respect to FIG. 1. For instance, mixer 204, amplifiers 206 and 212, and ADC 214 may correspond to receive signal chain 105. Mixer 205, amplifiers 209 and 213, and ADC 215 may correspond to receive signal chain 108.

In some embodiments, the differential output of LNTA 101 is split so that attenuator 102 is coupled to the positive and negative output terminals of LNTA 101, as is attenuator 103. In other embodiments, a first set of differential outputs of LNTA 101 is coupled to attenuator 102, and a second set of differential outputs of LNTA 101 is coupled to via attenuator 103. In either configuration, mixer circuit 204 is coupled to the positive and negative output terminals of LNTA 101 via attenuator 103. Similarly, mixer circuit 205 is coupled to the positive and negative output terminals of LNTA 101 via attenuator 103.

Each of the mixer circuits 204, 205 may be coupled to oscillator circuit 216. Oscillator circuit 216 may be implemented in any appropriate fashion, such as being implemented as a phase locked loop (PLL) or other appropriate circuit. The output of oscillator circuit 216 is split, so that the output of oscillator 216 that is received by mixer 205 is phase-shifted 90° by 90° phase shift circuit 217. By contrast, the output of oscillator 216 that is received by mixer 204 is not phase-shifted. Thus, mixer circuit 204 is implemented as in-phase, and mixer circuit 205 is implemented as quadrature-phase. Mixer circuits 204 and 205 are configured to receive the output of oscillator 216 and 90° phase shift circuit 217 at the respective clock inputs.

Each of mixer circuits 204 and 205 may include an adjustable gain. Furthermore, mixer circuits 204 and 205 may adjust a frequency of the RF signal down, such as from a gigahertz range to a megahertz range. However, the scope of implementations is not limited to any particular frequency range of operation. So although 3.2 GHz and 2.4 GHz are given as examples of RF signals processed by LNTA 101, the scope of implementations may include any appropriate frequency range of operation, such as between 5 GHz and 13 GHz, or different, such as higher than 13 GHZ, or lower than 2.3 GHZ, such as sub-1 GHz frequencies.

The mixers 204 and 205 down convert their respective I and Q current mode signals to an intermediate frequency or baseband. Furthermore, each of the mixers 204, 205 includes a differential current mode output.

In some embodiments, intermediate frequency amplifier (IFA) 206 receives the differential output from mixer 204 at its inputs and provides a gain adjusted differential voltage output. For instance, resistor 207 is coupled from positive input to positive output of IFA 206, and resistor 208 is coupled from negative input to negative output of IFA 206. Each of resistors 207 and 208 may be implemented to be adjustable to change a level of gain provided by IFA 206. Furthermore, IFA 206 may include an analog filter to reduce unwanted frequencies from the intermediate frequency or baseband signal.

IFA 209 may be implemented similarly to IFA 206. For instance, resistors 210 and 211 may be implemented similarly to resistors 207 and 208 to provide adjustable gain. Furthermore, IFA 209 may provide analog filtering to reduce unwanted frequencies from the intermediate frequency or baseband signal.

Variable gain amplifier (VGA) 212 may receive the gain adjusted differential output of IFA 206 and provide an adjustable gain to the I signal. VGA 213 receives the gain adjusted differential output of IFA 209 and provides an adjustable gain to the Q signal. VGA 212 and VGA 213 may be implemented as operational amplifiers or other appropriate amplifier circuit architecture. VGA 212 generates a differential output, which it provides to ADC 214. VGA 213 generates a differential output, which it provides to ADC 215. ADCs 214, 215 convert the respective I and Q signals from analog-to-digital and provide respective digital outputs to the digital processing circuit 110.

Receive AGC circuit 120 may control adjustable gain of the various components of system 200. For instance, receive AGC circuit 120 may provide control signals to each of the LNA 201, TAs 202 and 203, adjustable capacitive attenuators 103 and 106, mixers 204 and 205, resistors 207-211, and VGAs 212 and 213.

FIG. 3 is an illustration of an example architecture for use in LNTA 101, according to some embodiments. In FIG. 3, the outputs OUTP and OUTM correspond to M and P of FIGS. 1 and 2 respectively.

LNTA 101 includes four different cascode amplifiers. Transistors P1 and P2 form a first cascode amplifier, with transistor P1 being a common source stage of the cascode amplifier, and transistor P2 being a common gate stage of the cascode amplifier. Transistors N1 and N2 form another cascode amplifier, with N1 being a common source stage and N2 being a common gate stage.

Transistors P3 and P4 form another cascode amplifier, with P3 being a common source stage and P4 being a common gate stage. N3 and N4 form another cascode amplifier, with N3 being a common source stage and N4 being a common gate stage. Thus, each of the four cascode amplifiers includes a common source stage and a common gate stage.

The transistors labeled P in this embodiment are P type metal oxide semiconductor (PMOS) transistors, and the transistors labeled N in this embodiment are N type metal oxide semiconductor (NMOS) transistors. However, the scope of implementation is not limited to MOS devices, as other transistor technologies may be used as well, such as bipolar junction transistors (BJTs), and the like may be used. For instance, in a BJT arrangement, each cascode amplifier may be adapted to have a common emitter stage in a common base stage.

The cascode amplifier that includes N1 and N2 is coupled to the single-ended RF input (RF_IN) via capacitor 301. There is also a transformer coupled to the gate and source of transistor N1, where the transformer includes inductors 311 and 312, having opposite polarity windings. Inductor 311 is coupled between the gate of transistor N1 and a bias voltage (Vbias_N), and inductor 312 is coupled between the source of transistor N1 and ground. The gate of transistor N2 is coupled to another bias voltage (Vb_N_Casc), the source of transistor N2 is coupled to the drain of transistor N1, and the drain of transistor N2 is coupled to the drain of transistor P2. The drains of transistors N2 and P2 may be used as an output node for the output current OUTP.

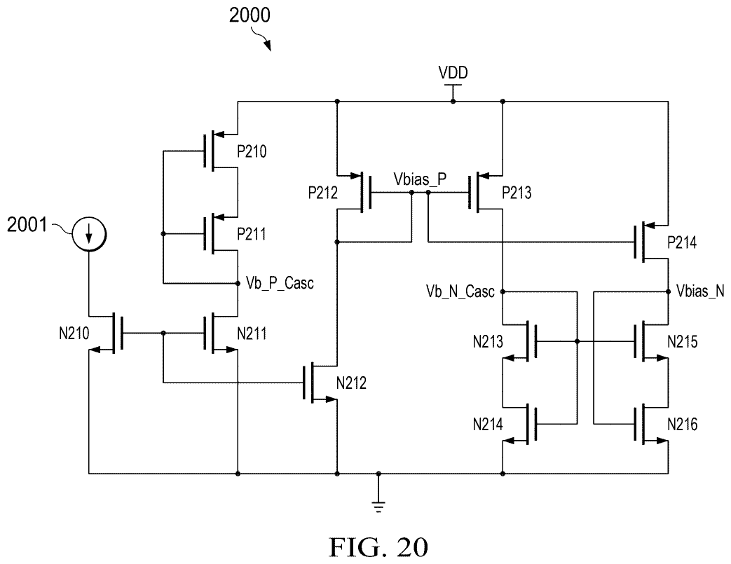

The cascode amplifier that includes transistors P1 and P2 is coupled to VDD at the source of transistor P1. The gate of transistor P1 is coupled to the RF input via capacitor 302 and capacitor 301. The gate of transistor P1 is also coupled to the drain of transistor P2 via resistor 321. The gate of transistor P2 is coupled to another bias voltage (Vb_P_Casc). The bias voltages Vbias_N, Vb_N_Casc, and Vb_P_Casc are described in more detail with respect to FIG. 20. In short, each of the bias voltages is a direct current (DC) voltage configured to cause a gate source voltage (Vgs) at its respective transistor sufficient to keep that transistor in its saturation operating region. In other words, in this example, each of the bias voltages is configured to keep its respective transistor in an on state during operation.

In some embodiments, the capacitors 301 and 302 may provide input matching for the LNTA 101. Similarly, capacitors 304 and 303 provide input matching for the structure that includes the cascode amplifier having transistors N3 and N4 and the cascode amplifier having transistors P3 and P4. Thus, in this example, input matching is performed using capacitors rather than, e.g., inductors.

The cascode amplifier that includes transistors N3 and N4 is coupled to ground by the source of transistor N3. The gate of N3 is coupled to the drain of N1 by capacitor 303. The gate of N3 is also coupled to the bias voltage Vbias_N via resistor 323. The source of transistor N4 is coupled to the drain of transistor N3, and the gate of transistor N4 is coupled to the bias voltage Vb_N_Casc. The drain of N4 is coupled to the drain of P4, and those drains may be used as an output node for the output current OUTM.

The cascode amplifier that includes transistors P3 and P4 may be coupled to VDD by the source of P3. The gate of P3 is coupled to the drain of P1 via capacitor 304, and the gate of P3 is also coupled to the drain of P4 via resistor 322. The gate of transistor P4 is coupled to the bias voltage Vb_P_Casc, and the source of P4 is coupled to the drain of P3.

During operation of LNTA 101, the RF input receives a single-ended RF voltage signal, such as via antenna 114, and outputs a current mode differential signal, where the positive and negative components of the output differential signal are OUTP (positive, +) and OUTM (negative,−). The RF input is coupled to the gate of transistor N1. As noted above, the transformer at the gate and source of N1 includes inductors 311 and 312 having opposite polarity windings, and inductor 312 couples the source of N1 to ground. Such arrangement supports the relationship between the gate and the drain of N1 to have a gain of −1. Thus, the RF input signal (RF_IN) is inverted at the drain of N1. In other words, the gate of N3 is coupled to the inverse of RF_IN.

The transistor P1 is coupled to VDD and also receives the RF input signal, and the voltage at the drain of P1 has a negative gain compared to the voltage at the gate of P1. The voltage at the drain of P1 is applied to the gate of P3. Thus, the four different cascode amplifiers provide a current mode differential output signal. As noted above in FIGS. 1 and 2, the differential current mode output signal may be applied to one or more signal chains, such as an I signal chain and a Q signal chain.

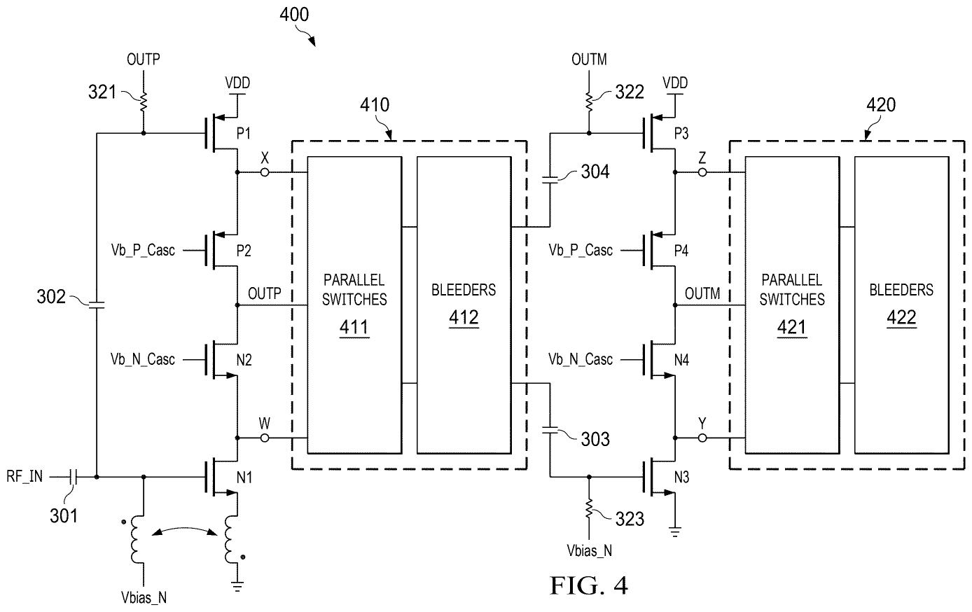

The architecture shown in FIG. 3 is an example architecture that may be used for LNTA 101. Other embodiments may adapt the architecture of FIG. 3 to include gain adjustable components, such as described below with respect to FIGS. 4-21.

FIG. 4 is an illustration of an example LNTA 400, according to some embodiments. LNTA 400 is implemented using an architecture that may also be used for LNTA 101 of FIGS. 1 and 2 in the examples above. LNTA 400 allows for gain adjustability. In FIG. 4, the outputs OUTP and OUTM correspond to M and P of FIGS. 1 and 2 respectively.

LNTA 400 includes transistors P1-P4 as well as transistors N1-4, as described above with respect to FIG. 3. However, LNTA 400 adds controllable circuit 410 and controllable circuit 420. FIG. 4 illustrates node X, at which the drain of transistor P1 couples to the parallel switches 411, node W, at which the source of transistor N1 and the drain of N2 are coupled to parallel switches 411, node Y, at which the source of N4 and the drain of N3 are coupled to parallel switches 421, and node Z, at which the drain of P3 and the source of P4 coupled to the parallel switches 421.

In some embodiments, bleeders 412 are coupled to the parallel switches 411 as well as to the gate of transistor P3 via capacitor 304. Bleeders 412 are also coupled to the gate of N3 via capacitor 303. Parallel switches 411 are also coupled to OUTP at the drain of P2 and the drain of N2.

In some embodiments, parallel switches 421 are coupled to bleeders 422 and to OUTM at the drain of P4 and the drain of N4. Controllable circuits 410 and 420 may allow for gain control by reducing a current level at the outputs OUTP and OUTM.

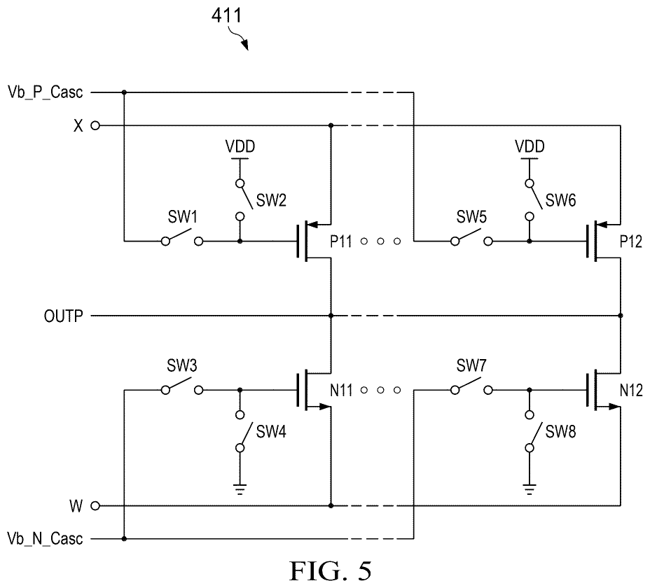

FIG. 5 is an illustration of an example architecture for parallel switches 411. Transistors P11 and N11 form a first leg (leg 1), and transistors P12 and N12 form a second leg (leg N). The indices 0-N indicate that parallel switches 411 may include any appropriate number of legs N, where N is an integer. Thus, the ellipses in FIG. 5 indicate other legs that may be present but not shown and configured similarly to the legs 0 and N.

Transistor P11 is coupled at its source to node X and at its drain to the output OUTP. Transistor N11 is coupled at its drain to OUTP and to the drain of P11, and its source is coupled to the node W. Transistor P11 has a gate that may be selectively coupled to either Vb_P_Casc or to VDD by respective switches SW1 and SW2. Similarly, transistor N11 has a gate that may be selectively coupled either to Vb_N_Casc or ground by respective switches SW3 and SW4.

Transistors P12 and N12 may be configured similarly to transistors P11 and N11. Specifically, transistor P12 is coupled at its source to node X and to its drain to the output OUTP. Transistor N12 is coupled at its drain to the drain of P12 and OUTP and coupled that its source to node W. The gate of transistorP12 is selectively coupled to either VDD or Vb_P_Casc by respective switches SW5 and SW6. The gate of transistor N12 is coupled to either Vb_N_Casc or to ground by respective switches SW7 and SW8.

The leg including transistor P11 and N11 may be turned on when switches SW1 and SW3 are closed (SW2 and SW4 are open) and may be turned off when switches SW2 and SW4 are closed (SW1 and SW3 are open). The leg including transistors P12 and N12 is operated similarly.

Switches SW1-8 may be individually controllable by, e.g., receive gain control circuit 120 providing control signals. In some embodiments, switches SW1-8 may be implemented using transistors or other appropriate technology to be either closed or open (e.g., off or on). When a given leg is on, it conducts current from node X to node Y.

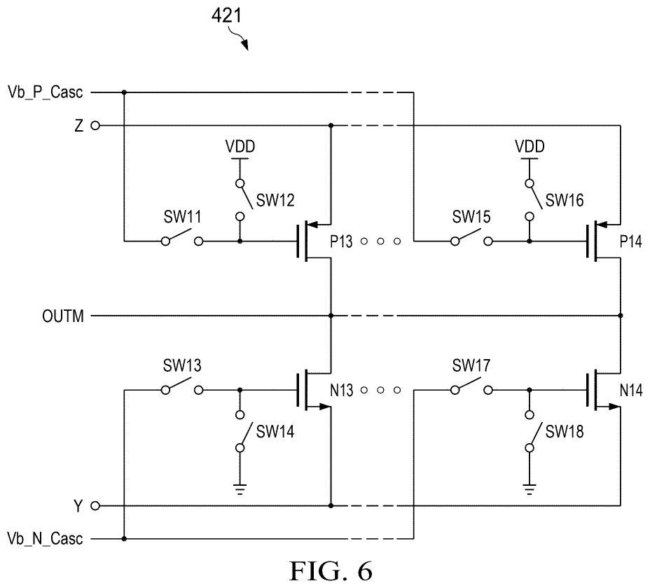

FIG. 6 is an illustration of an example architecture for parallel switches 421. Parallel switches 421 are configured similarly to parallel switches 411, having N legs, where a first leg (leg 1) is shown by transistors P13 and N13, and leg N is shown by transistors P14 and N14.

The drains of transistors P13 and N13 are coupled to the output OUTM (rather than to OUTP in FIG. 5), and the same thing is true of transistors P14 and N14. Transistor P13 is implemented similarly to transistor P11, having switches SW11 and SW12 to selectively couple its gate to either Vb_P_Casc or to VDD. Transistor N13 is implemented similarly to transistor N11, having switches SW 13 NSW 14 to selectively coupled its gate to either Vb_N_Casc or to ground. Transistor P14 is implemented similarly to transistor P12, having switches SW15 and SW16 to selectively couple its gate to either Vb_P_Casc or to VDD. Transistor N14 is implemented similarly to transistor N12, having switches SW17 and SW18 to couple its gate to either Vb_N_Casc or to ground.

When a given leg is on, it conducts current from node Z to node Y.

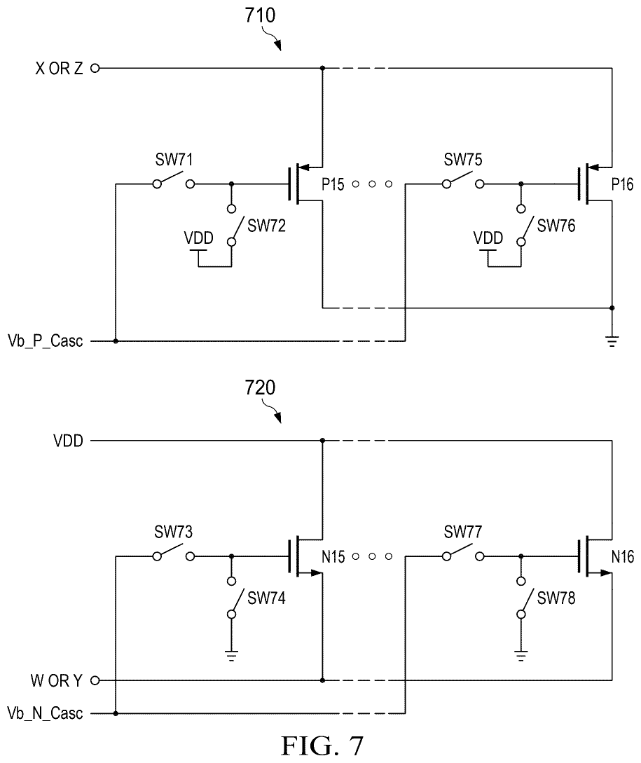

FIG. 7 is an illustration of an example bleeder circuit, either bleeders 412 or bleeders 422, according to some embodiments. For example, for bleeders 412, the source of P15 and the source ofP16 would be coupled to node X, and the drain of N15 and the drain of N16 would be coupled to node Y, as illustrated.

In the top half structure 710, transistor P15 is configured so that its drain is coupled to ground, and the same is true of transistor P16. The ellipses indicate that there may be further legs (not shown), such that P15 corresponds to a first leg, and P16 corresponds to an Mth leg. M may be any appropriate positive integer. The gate of transistor P15 may be selectively coupled to either VDD via switch SW72 or to bias voltage Vb_P_Casc via switch SW71. Transistor P16 is arranged similarly, though with switches SW75 and SW76. When transistor P15 is turned on, it conducts current between node X or Z and ground. The same is true of transistor P16. For transistors P15 and P16, having a gate coupled to VDD corresponds to an off state, and having a gate coupled to the bias voltage corresponds to an on state.

In the bottom half structure 720, transistor N15 is arranged so that its drain is coupled to VDD. The gate of transistor N15 is selectively coupled to either bias voltage Vb_N_Casc or ground via respective switches SW73 and SW74. Transistor N16 is configured similarly, with switches SW77 and SW78. When transistor N15 is turned on, it conducts current between VDD and node W or node Y. The same is true of transistor N16. For transistors N15 and N16, having a gate coupled to ground corresponds to an off state, and having a gate coupled to the bias voltage corresponds to an on state. Bleeders 412 and 422 may provide attenuation by “bleeding” some of the current from OUTP and OUTM to VDD and ground, depending on the quantity of legs that are turned on.

As with FIGS. 5 and 6, the switches (SW71-SW78) may be configured to be controlled by control signals from receive AGC circuit 120 to control gain of LNTA 400.

In one example implementation, parallel switches 411 may be configured so that N+1 is 64, and parallel switches 421 may be configured similarly. Bleeders 412 may be configured so that M is 64, and bleeders 422 may be configured similarly. Of course, that is just an example, and other embodiments may be scaled as appropriate.

As noted above with respect to FIGS. 4-5, each of the legs may provide a current path parallel to a current path provided by respective cascodes. For instance, parallel switches 411 may provide legs that are parallel to the current path provided by transistors P2 and N2. Thus, if N is 63, then N+1 is 64 and includes the current path provided by transistors P2 and N2. Similarly, parallel switches 421 may provide legs that are parallel to the current path provided by the P4 and N4.

In one example method of use, receive AGC circuit 120 may generate control signals for the LNTA 400 to provide a multitude of gain steps, where each gain step represents a level of attenuation that may be provided by the controllable circuits 411-412 and 421-422.

FIG. 8 is an illustration of a multitude of gain steps, which may be implemented by receive AGC circuit 120, to provide a multitude of gain steps for operation of LNTA 400, according to some embodiments.

In some embodiments, gain step 1 corresponds to a most amount of gain (e.g., a least amount of attenuation) available in one example in which N is 63 and M is 64. The receive AGC circuit 120 may be configured so that each of the different gain steps is associated with a quantity (A) of parallel switches that are on (e.g., a quantity of legs on in each of 411 and 421) plus one to account for the current path provided by transistors P2 and N2. That quantity is represented as A+1 in the middle column of FIG. 8. The receive AGC circuit 120 may be configured so that each of the different gain steps is also associated with a quantity of bleeder devices (e.g., quantity of legs in each of 412 and 422) that are turned on. That quantity is represented as B in the right-hand column of FIG. 8. The receive AGC circuit 120 may be configured so that the relationship between A and B for every gain step is that A+1 plus B equals 64.

Of course, in this example, such a relationship may be appropriate because N+1 and M are both 64. In an example in which N+1 and M are both 128, then the relationship between A and B may be set so that A+1 plus B always equals 128. Various embodiments may be configured as appropriate.

Gain step 2 corresponds to a second most amount of gain and a second least amount of attenuation. In this example, A+1 and B both equal 32 and sum to 64. The gain steps continue one-by-one from gain step 2 to gain step 7, where each of the values of A+1 is equal to a power of 2. Thus, the final available gain step is gain step 7, where A+1 is equal to 1. Gain step 7 corresponds to the least amount of gain and the most amount of attenuation available in this example.

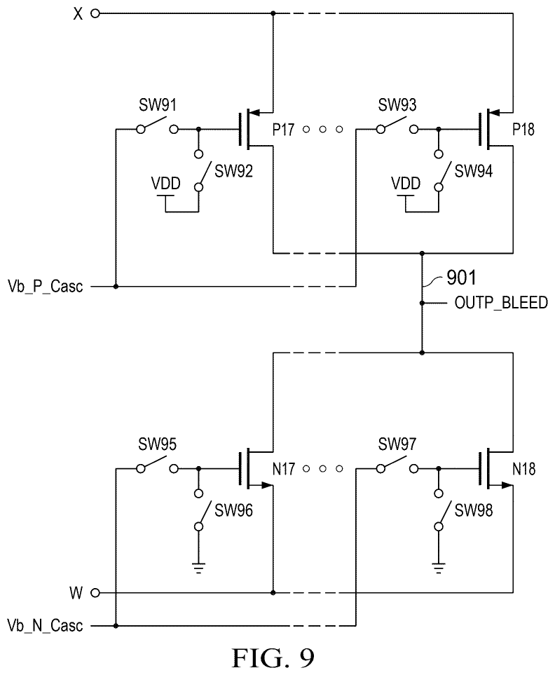

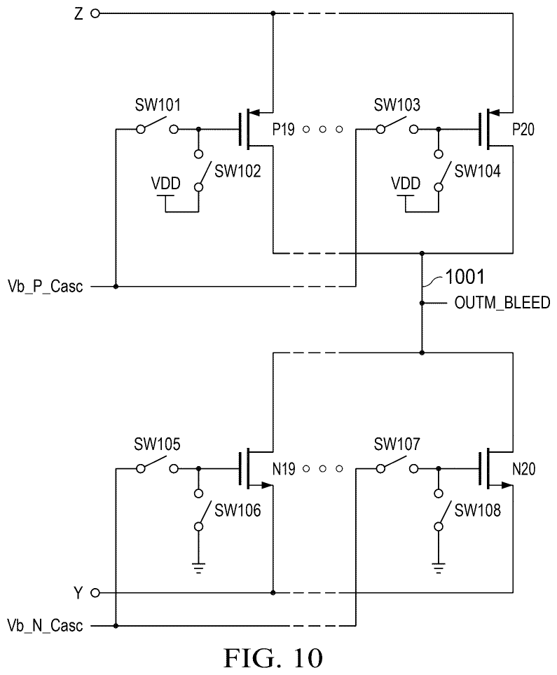

FIGS. 9 and 10 illustrate example implementations for bleeders 412 and 422, respectively, according to some embodiments. The examples of FIGS. 9 and 10 differ from the example of FIG. 7 in that the bleeders do not bleed current to either VDD or ground. Rather, the legs in the bleeders of FIGS. 9 and 10 are coupled to common bias point OUTP_BLEED or OUTM_BLEED.

FIG. 9 illustrates an example architecture for bleeders 412. Transistors P17 and N17 illustrate a first leg, and transistorsP18 and N18 illustrate an Mth leg, as the architecture provides for M legs, similar to the example of FIG. 7. Transistors P17 and P18 are coupled at their sources to node X and at their drains to conductor 901, which may be used as an output terminal for OUTP_BLEED. The gate of transistor P17 is coupled to either VDD or bias voltage Vb_P_Casc by respective switches SW92 and SW91. The gate of transistor P18 is coupled in a similar manner by respective switches SW94 and SW93.

Transistors N17 and N18 are coupled by their sources to node W and by their drains to OUTP_BLEED. Transistor N17 is coupled to either bias voltage Vb_N_Casc or ground by respective switches SW95 and SW96. N18 is similarly configured having switches SW97 and SW98.

In this example, when transistors P17 and N17 are turned on, that leg is turned on, and when transistors P17 and N17 are turned off, that leg is turned off. The same is true for other legs.

FIG. 10 illustrates an example architecture for bleeders 422. Bleeders 422 are arranged similarly to bleeders 412, except that bleeders 422 conduct current to OUTM_BLEED at the drains of P19 and P20 and at the drains of N19 and N20 via conductor 1001. In this example, transistors P19 and N19 represent a leg, and transistorsP20 and N20 represent another leg, and there may be M legs.

Transistors P19 and P20 are coupled between node Z and OUTM_BLEED by their sources and drains. The gates of transistors P19 and P20 are selectively coupled to either VDD or Vb_P_Casc by their switches SW101 and SW 102 (for P19) and SW103 and SW104 (for P20). Transistors N19 and N20 are coupled at their sources to node Y and at their drains to OUTM_BLEED. The gates of transistors N19 and N20 are selectively coupled to either Vb_N_Casc or ground by their switches SW105 and SW106 (for N19) and SW107 and SW108 (for N20).

In one example, LNTA 400 is configured so that parallel switches 411 are configured according to FIG. 5, parallel switches 421 are configured according to FIG. 6, bleeders 412 are configured according to FIG. 9, and bleeders 422 are configured according to FIG. 10. The number of legs in each of the parallel switches 411 and 421 may be N, and the number of legs in each of the bleeders 412 and 422 may be M.

During operation, the receive AGC circuit 120 may be configured as described above with respect to FIG. 8. That is, the receive AGC circuit 120 may generate control signals for the switches SW1-SW7, SW11-SW17, SW91-SW98, and SW101-SW108 to implement the gain steps of FIG. 8. Of course, as noted above, the specific gain steps of FIG. 8 may be used in a scenario in which N+1 is 64 and M is also 64. As the number of legs in the parallel switches and in the bleeders is scaled, the gain steps may be reconfigured as appropriate. As with the examples above, more bleeder legs turned on provides greater attenuation, and fewer bleeder legs turned on provides less attenuation.

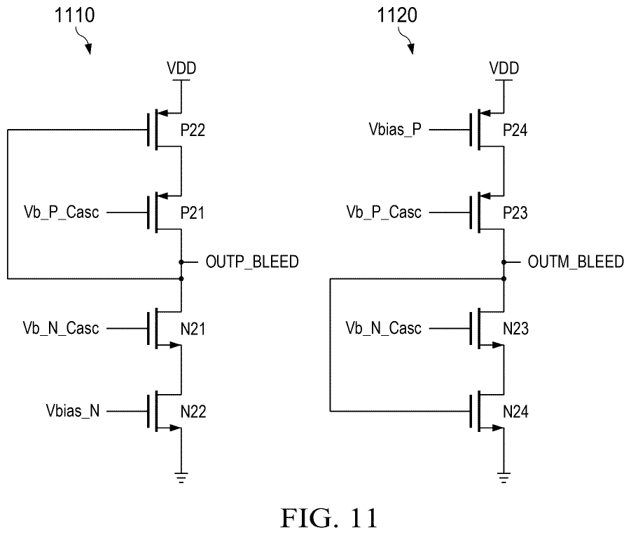

FIG. 11 shows example circuits 1110, 1120, which may be used to provide the common bias points OUTP_BLEED and OUTM_BLEED, according to some embodiments.

Circuit 1110 includes two different cascode amplifiers arranged between VDD and ground. A first cascode includes transistors P21 and P22, and a second cascode amplifier includes N21 and N22. The source of P22 is coupled to VDD, and the drain of P22 is coupled to the source of P21. The gate of P22 is shorted to the drain ofP21. The gate of P21 is coupled to the bias voltage Vb_P_Casc. The drain of N21 is coupled to the drain of P21, and the source of N is coupled to the drain of N22. The source of N22 is coupled to ground. The gate of N21 is coupled to the bias voltage Vb_N_Casc, and the gate of N22 is coupled to the bias voltage Vbias_N.

Circuit 1120 also includes two different cascode amplifiers. A first cascode amplifier includes transistors P23 and P24, and a cascode amplifier includes transistors N23 and N24. Transistor P24 is configured so that its source is coupled to VDD, and its drain is coupled to the source of P23. The gate of transistorP24 is coupled to the bias voltage Vbias_P, and the gate of P23 is coupled to the bias voltage Vb_P_Casc. The drain of N23 is coupled to the drain of P23, and the source of N23 is coupled to the drain of N24. The gate of N23 is coupled to the bias voltage Vb_N_Casc, and the gate of N24 is shorted to the drain of N23.

In circuit 1110, the drains of P21 and N21 serve as a node at which the bias voltage OUTP_BLEED is output, and in circuit 1120, the drains of P23 and N23 serve as a node at which the bias voltage OUTM_BLEED is output.

In the example of FIG. 11, the bias voltages may be all DC voltages, and the output voltages OUTP_BLEED and OUTM_BLEED may also be DC voltages.

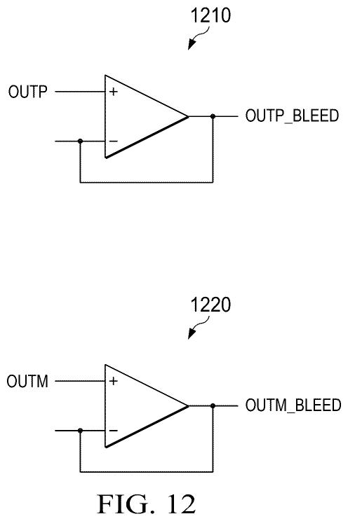

FIG. 12 shows example circuits 1210, 1220, which may be used to provide the common bias points OUTP_BLEED and OUTM_BLEED, according to some embodiments.

Circuit 1210 is an operational amplifier, having an inverting (−) input terminal and a non-inverting (+) input terminal. The output terminal may be used as a common bias point for OUTP_BLEED. The output terminal may be coupled to the inverting input terminal, and the non-inverting input terminal may be coupled to the drains of transistors P2 and N2. As a result, the output terminal may provide a relatively constant DC biasing voltage associated with OUTP_BLEED, which may be equal to or nearly equal to the DC component of OUTP.

Similarly, circuit 1220 has an inverting input, a non-inverting input, and an output terminal. The non-inverting input terminal may be coupled to the drains of P4 and N4. The output terminal may be coupled to the inverting input. As a result, the output terminal may provide a relatively constant DC biasing voltage associated with OUTM_BLEED, which may be equal to or nearly equal to the DC component of OUTM.

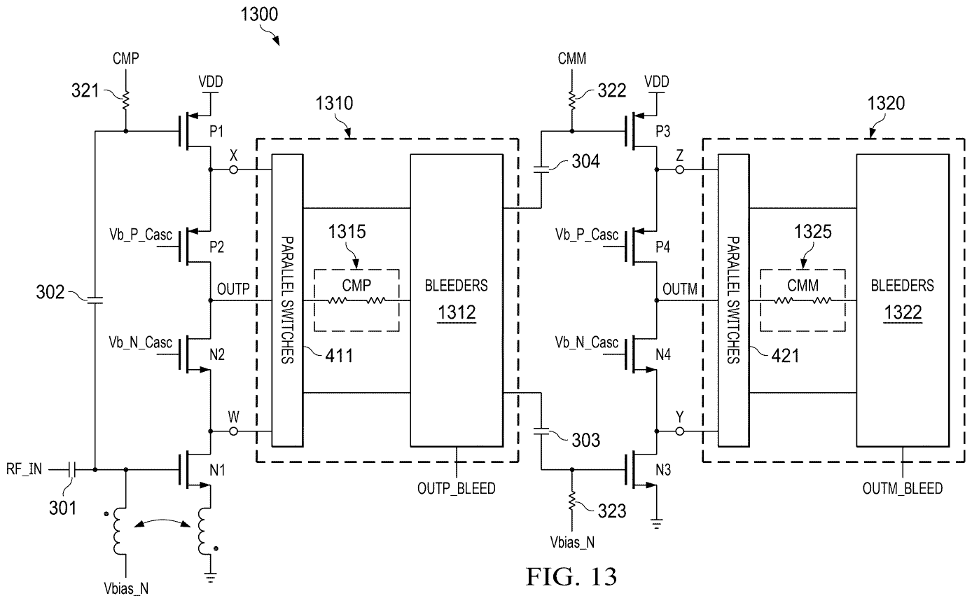

FIG. 13 is an illustration of an example LNTA 1300, according to some embodiments. LNTA 1300 illustrates an architecture that may be used for LNTA 101 of FIGS. 1 and 2.

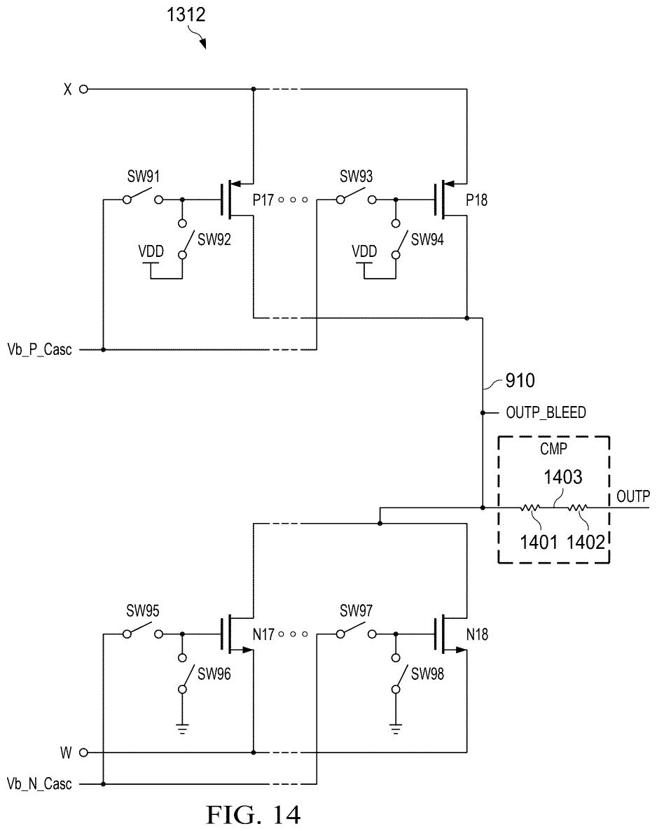

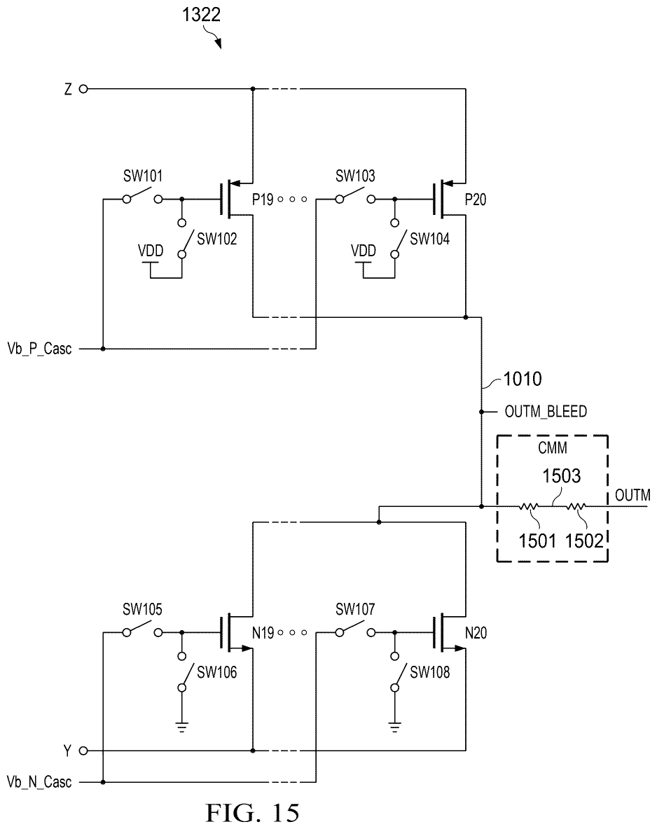

LNTA 1300 is similar to LNTA 1400, though LNTA 1300 includes controllable circuits 1310 and 1320. Controllable circuit 1310 includes parallel switches 411, bleeders 1312 and common mode component 1315. Bleeders 1312 are described in more detail with respect to FIG. 14. Controllable circuit 1320 includes parallel switches 421, bleeders 1322, and common mode component 1325. Bleeders 1322 are described in more detail below with respect to FIG. 15.

The common mode component 1315 is coupled to OUTP and to a terminal of resistor 321. Common mode component 1325 is coupled to OUTM and to a terminal of resistor 322. As in the examples above, bleeders 1312 and 1322 may be used to provide attenuation, thereby adjusting a gain of LNTA 1300.

FIG. 14 is an illustration of bleeders 1312, according to some embodiments. Bleeders 1312 may be implemented similarly to the bleeders of FIG. 9, though a difference is that bleeders 1312 include resistors 1401 and 1402 and conductor 1403.

Resistors 1401 and 1402 and conductor 1403 illustrate common mode component 1315 of FIG. 13. Resistor 1401 has a first terminal coupled to conductor 910, which is coupled to the drains of P17 and P18 and to the drains of N17 and N18 and to OUTP_BLEED. Conductor 1403 is coupled between resistors 1401 and 1402, and resistor 1402 has a terminal coupled to OUTP. As in the example of FIG. 9, bleeders 1312 bleed current to the common bias point OUTP_BLEED. Conductor 1403 may be further coupled to resistor 321 in the example of FIG. 13. During operation, conductor 1403 is at common mode voltage CMP.

FIG. 15 is an illustration of bleeders 1322, according to some embodiments. Bleeders 1322 may be implemented similarly to the bleeders of FIG. 10, though a difference is that bleeders 1322 include resistors 1501 and 1502 and conductor 1503.

Resistor 1501 has a terminal that is coupled to the drains of P19 and P20 and to the drains of N19 and N20 as well as to the common bias point OUTM_BLEED. Conductor 1503 is coupled between resistors 1501 and 1502, and a terminal of resistor 1502 is coupled to OUTM. Furthermore, conductor 1503 may be coupled to resistor 322 in the example of FIG. 13. During operation, conductor 1503 is at common mode voltage CMM.

A potential advantage of the embodiments of FIGS. 13-15 versus those described above with respect to FIGS. 9-10 is that the common mode components 1315 and 1325 may reduce a source-drain voltage mismatch between the transistors of the bleeders and the transistors of the parallel switches. Reducing such a mismatch may increase linearity of operation of LNTA 1300.

Receive AGC circuit 120 may control LNTA 1300, to turn on or off legs in the controllable circuits 1310, 1320 as described above with respect to FIG. 8. For instance, more legs turned on in the bleeders 1312 and 1322 may provide more attenuation (e.g., less gain) and fewer legs turned on in the bleeders 1312 and 1322 may provide less attenuation (e.g., more gain). Furthermore, the receive AGC circuit 120 may control LNTA 1300 to provide multiple, discrete gain steps, the same as or similar to those discussed above with respect to FIG. 8.

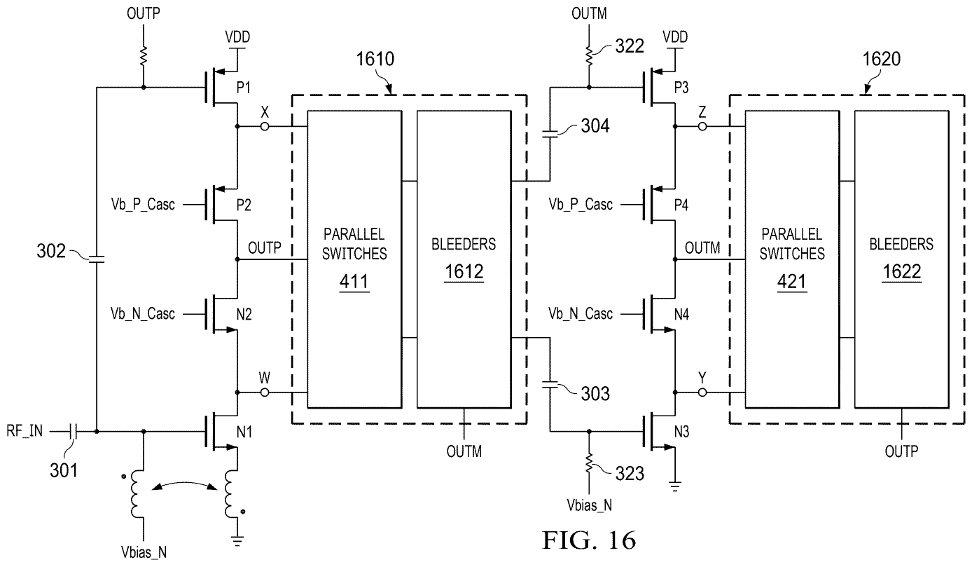

FIG. 16 is an illustration of example LNTA 1600, according to some embodiments. Example LNTA 1600 illustrates an architecture that may be used for LNTA 101 of FIGS. 1 and 2. LNTA 1600 includes controllable circuits 1610 and 1620. Controllable circuit 1610 includes parallel switches 411 and bleeders 1612, where bleeders 1612 are coupled to OUTM. Controllable circuit 1620 includes parallel switches 421 and bleeders 1622, where bleeders 1622 are coupled to OUTP.

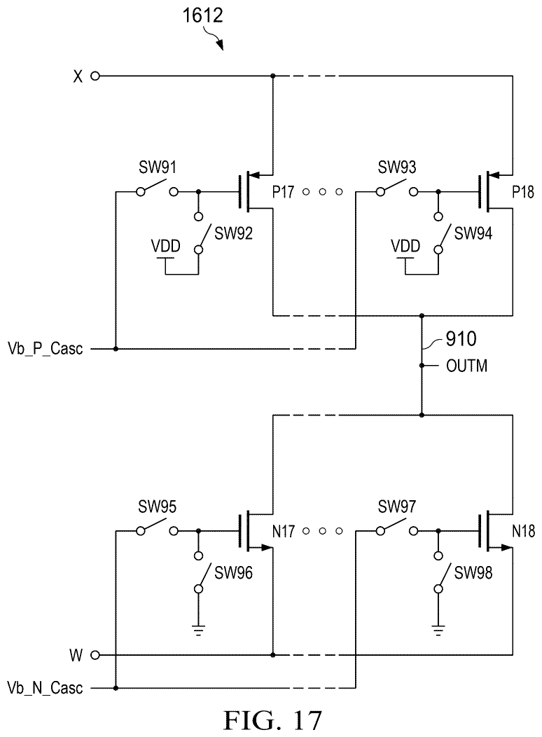

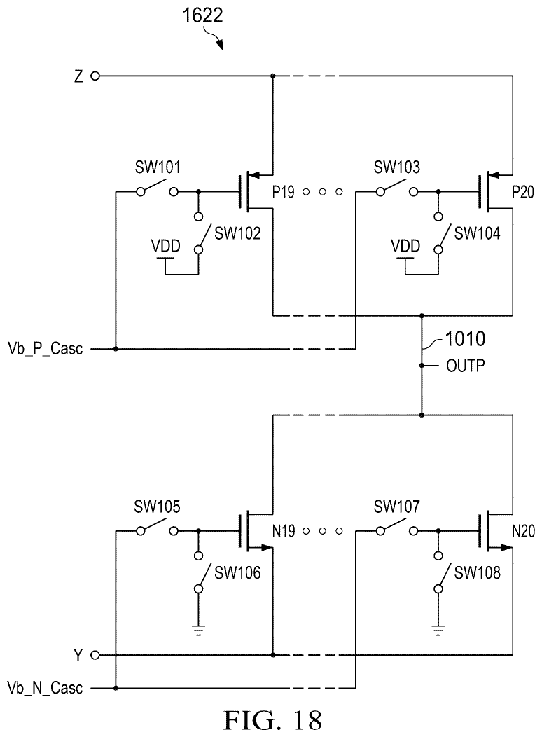

Example architectures for bleeders 1612 and 1622 are described in more detail below with respect to FIGS. 17 and 18. In short, bleeders 1612 may provide attenuation by bleeding current from OUTP to OUTM. Similarly, bleeders 1622 may provide attenuation by bleeding current from OUTM to OUTP. A potential advantage of the embodiments of FIGS. 16-18 over the embodiments of FIGS. 13-15 is that the embodiments of FIGS. 16-18 may even further reduce a source-drain voltage mismatch between transistors of the parallel switches and transistors of the bleeders. As a result, the embodiments of FIGS. 16-18 may provide improved linearity of operation.

FIG. 17 is an illustration of example bleeders 1612, according to some embodiments. Bleeders 1612 are configured similarly to the bleeders of FIG. 9, though bleeders 1612 include conductor 910 being coupled to OUTM. Thus, the negative output signal OUTM is coupled to the drains of P17 and P18 and to the drains of N17 and N18 by conductor 910.

FIG. 18 is an illustration of example bleeders 1622, according to some embodiments. Bleeders 1622 are configured similarly to the bleeders of FIG. 10, though bleeders 1622 include conductor 1010 being coupled to the positive output signal OUTP. The positive output signal OUTP is coupled to the drains of P19 and P20 and to the drains of N19 and N20 by conductor 1010. When a leg of bleeder 1612 is turned on, it causes some of the current from OUTP to be drained to OUTM. Similarly, when a leg of bleeder 1622 is turned on, it causes some of the current from OUTM to be drained to OUTP. Thus, the attenuation provided by each of bleeders 1612 and 1622 is analogous to destructive interference.

FIG. 19 is an illustration of a table illustrating multiple gain steps that may be implemented by receive AGC circuit 120, with respect to LNTA 1600, according to some embodiments. Specifically, receive AGC circuit 120 may generate control signals to control the switches SW91-SW98 and SW101-SW108 to either turn on or turn off a respective transistor. Each respective transistor may be included within a leg, so that the transistors within a single leg are turned on or turned off together. For example, P17 and N17 may correspond to one leg in bleeders 1612, and P19 and N19 may correspond to one leg in bleeders 1622. In the example of FIG. 19, N+1 and M are both equal to 64, though the scope of implementations may include systems that are scaled differently than 64. The more legs of bleeders 1612 and 1622 that are turned on, the greater the attenuation (e.g., the lower the gain) and vice versa.

FIG. 19 includes multiple columns. The columns labeled OUTP and OUTM illustrate a proportion of gain for OUTP and OUTM, respectively, at each gain step. Each gain step is given by a row. The column OUTP-OUTM subtracts the proportion of gain in the OUTM column from the proportion of gain in the OUTP column.

The quantity A+1 is a quantity of legs (A) in each of parallel switches 411 and 421 that are turned on plus one to account for the corresponding cascode. This is the same as in FIG. 8. The quantity B is a quantity of legs in each of the bleeders 1612 and 1622 that are turned on. This is the same as in FIG. 8. And, just as in FIG. 8, the sum of A+1 and B is held equal to 64 throughout the gain steps.

However, the gain steps of FIG. 19 are different from the gain steps of FIG. 8 in that the gain steps of FIG. 19 are configured so that A+1-B follows powers of two. For instance, gain step 1 has A+1-B=64, for gain step 2, A+1-B=32, and so on. As a result, the quantity A decreases less from the first gain step (1) to the last gain step (6) than it does in the example of FIG. 8.

FIG. 20 is an illustration of an example bias circuit 2000, according to some embodiments. Bias circuit 2000 may be used in some implementations to provide the DC bias voltages Vbias_N, Vb_P_Casc, Vbias_P, and Vb_N_Casc discussed above to provide biasing to the transistors of LNTA 101, LNTA 400, LNTA 1300, LNTA 1600, the circuits of FIGS. 11 and 12, and the various parallel switches and bleeders. In this example, the bias circuit 2000 is static, so that during normal operation, it provides bias voltages that are stable.

Bias circuit 2000 includes current source 2001 coupled to a drain of transistor N210, and the source of transistor N210 is coupled to ground. The gate of transistor N210 is shorted to the gate of transistor N211 and to the gate of transistor N212.

Bias circuit 2000 includes four different legs coupled between VDD and ground. A first leg includes transistors P210, P211, and N211. A second leg includes transistor P212 and N212. A third leg includes transistors P213, N213, and N214. The fourth leg includes transistors P214, N215, and N216.

Transistor P210 is coupled at its source to VDD and at its drain to the source of P211. The drain of P211 is coupled to the drain of N211, and the source of N211 is coupled to ground. The gates of P210 and P211 are shorted to each other and further shorted to the drain of P211. The drain of P211 (the drain of N211 as well) is configured as a node that provides the bias voltage Vb_P_Casc.

Transistor P212 is coupled at its source to VDD and at its drain to the drain of N212. The source of N212 is coupled to ground. The drain of N212 and the drain of P212 are coupled to the gate of P212, and the gates of P212, P213, and P214 are shorted together. Transistor P213 is coupled at its source to VDD and at its drain to the drain of N213. N213 is coupled at its source to the drain of N214, which is coupled at its source to ground. The drain of P213 and the drain of N213 is configured as a node that provides the bias voltage Vb_N_Casc. The gate of N214 is shorted to the gate of N213 and to the drain of P213. The shorted gates and the drawing of P212 is configured as a node that provides the bias voltage Vbias_P.

Transistor P214 is coupled at its source to VDD and at its drain to the drain of N215. The drain of P214 and the drain of N215 are configured as a node that provides the bias voltage Vbias_N. The source of N215 is coupled to the drain of N216, the source of which is coupled to ground. The gate of N216 is coupled to the drain of N215.

Of course, the scope of implementations may include any appropriate bias circuit that may be used to provide the various bias voltages, with example bias circuit 2000 being one example. Any bias circuit architecture operable to provide appropriate bias voltages may be used. As noted above, the various bias voltages are configured to maintain their respective transistors in a saturation region of operation during use.

FIG. 21 is an illustration of receive AGC circuit 120, according to some embodiments. Specifically, receive AGC circuit 120 of FIG. 21 is configured to provide appropriate control signals to the various components of the embodiments of FIGS. 1-20 to control gain across both the I signal path and the Q signal path.

In one example, receive AGC circuit 120 may measure a signal level at the ADCs 214 and 215, as illustrated by the input signals From ADC_I and from ADC_Q. The receive AGC circuit 120 may measure the gain using any appropriate technique, such as measuring an amplitude of current or voltage at the input of the ADC, measuring a signal swing at the input of the ADC, measuring a signal swing at the output of the ADC, receiving digital measurements from the ADC itself, and/or the like. In any event, measuring the signal provides a representation of the total gain provided by the signal path and its various components.

In response to the signal measurements, receive AGC circuit 120 may provide control signals to control gain. For instance, the signals AGC VGA_I and AGC VGA_Q may be used to control gain at VGAs 212 and 213. The signals AGC IFA_I and AGC IFA_Q may be used to control gain at the IFAs 206 and 209, such as by adjusting the resistors 207, 208, 210, and 211. In another example, the receive AGC circuit 120 may use the signals AGC IFA_I and AGC IFA_Q to adjust a filtering property of IFAs 206 and 209 as appropriate. The signals AGCO-AGCN may be used to adjust gain levels at one or more of the adjustable capacitive attenuator circuits (e.g., 102 and 103).

The signal AGC LNTA may be used to adjust the LNTA gain. More specifically, the signal AGC LNTA may be configured as a multitude of control signals to open and close the switches (SW) of the embodiments discussed above at FIGS. 5-7, 9-10, 14-15, and 17-18. The signals Parallel switchesM 0-N may include control signals to turn on or off the switches associated with individual legs of parallel switches 421. Similarly, the signals Parallel switchesP 0-N may include control signals to turn on or off the switch is associated with individual legs of parallel switches 411. Thus, receive AGC circuit 120 may be configured to individually control each of the legs 0-N in the parallel switches 411 and 421 to achieve a desired gain setting, such as described above with respect to FIGS. 8 and 19.

The signals BleedersM 0-M may be used to turn on or off individual legs of the bleeder circuits described above with respect to FIGS. 7, 10, 15, and 18. The signals BleedersP 0-M may be used to turn on or off individual legs of the bleeder circuits described above with respect to FIGS. 7, 9, 14, and 17. The receive AGC circuit 120 may be configured to individually control the legs of the bleeder circuits to achieve a desired gain setting, such as described above with respect to FIGS. 8 and 19.

Example embodiments of the present disclosure are summarized here. Other embodiments can also be understood from the entirety of the specification and the claims filed herein.

Example 1. An electronic circuit including: first and second output terminals; an input terminal; a first cascode amplifier having first and second control terminals and first and second current path terminals, where the first control terminal of the first cascode amplifier is coupled to the input terminal, and where the second current path terminal of the first cascode amplifier is coupled to the first output terminal; a second cascode amplifier having first and second control terminals and first and second current path terminals, where the first control terminal of the second cascode amplifier is coupled to the first current path terminal of the first cascode amplifier via a first capacitor; a third cascode amplifier having first and second control terminals and first and second current path terminals, where the second current path terminal of the third cascode amplifier is coupled to the first output terminal, and where the second current path terminal of the third cascode amplifier is coupled to the second output terminal; a fourth cascode amplifier having first and second control terminals and first and second current path terminals, where the first control terminal of the fourth cascode amplifier is coupled to the first current path terminal of the third cascode amplifier via a second capacitor, and where the second current path terminal of the fourth cascode amplifier is coupled to the second output terminal; and a controllable circuit including: a quantity (N) of first components, each first component having a first transistor arranged between the first current path terminal of the first cascode amplifier and the second current path terminal of the first cascode amplifier and a second transistor arranged between the first current path terminal of the third cascode amplifier and the second current path terminal of the third cascode amplifier, where N is an integer equal to or greater than 1, and a quantity (M) of second components, each second component having a first transistor coupled to the first current path terminal of the first cascode amplifier, and a second transistor coupled to the first current path terminal of the third cascode amplifier, where M is an integer greater than 1.

Example 2. The electronic circuit of example 1, where the first transistor of each first component has a control terminal having controllable coupling to a first polarity power supply and to a first bias voltage, where the second transistor of each first component has a control terminal having controllable coupling to a second polarity power supply and to a second bias voltage.

Example 3. The electronic circuit of one of examples 1 or 2, where the first transistor of each second component is coupled between the first current path terminal of the first cascode amplifier and a first polarity power supply, and the second transistor of each second component is coupled between the first current path terminal of the third cascode amplifier and a second polarity power supply.

Example 4. The electronic circuit of one of examples 1 to 3, where the first transistor of each second component has a control terminal having controllable coupling to the second polarity power supply and to a first bias voltage, where the second transistor of each first component has a control terminal having controllable coupling to the first polarity power supply and to a second bias voltage.

Example 5. The electronic circuit of one of examples 1 to 4, where the first transistor of each second component is coupled between the first current path terminal of the first cascode amplifier and a conductor, and the second transistor of each second component is coupled between the first current path terminal of the third cascode amplifier and the conductor.

Example 6. The electronic circuit of one of examples 1 to 5, where the first transistor of each second component has a control terminal having controllable coupling to the second polarity power supply and to a first bias voltage, where the second transistor of each first component has a control terminal having controllable coupling to the first polarity power supply and to a second bias voltage.

Example 7. The electronic circuit of one of examples 1 to 6, where the conductor is coupled to a current path terminal of a third transistor, where the third transistor has a control terminal coupled to a first bias voltage, where the first bias voltage is coupled to the first cascode amplifier, where a control terminal of a fourth transistor is coupled to the current path terminal of the third transistor, and where the fourth transistor is arranged between the second polarity power supply and the third transistor.

Example 8. The electronic circuit of one of examples 1 to 7, where the conductor is coupled to an output terminal of an amplifier and to a first input terminal of the amplifier, where a second input terminal of the amplifier is coupled to the second current path terminal of the first cascode amplifier.

Example 9. The electronic circuit of one of examples 1 to 8, where the first transistor of each second component is coupled between the first current path terminal of the first cascode amplifier and a first conductor and, the second transistor of each second component is coupled between the first current path terminal of the third cascode amplifier and the first conductor, where the first conductor is coupled to a first resistor, a second conductor, and a second resistor, where the first resistor, the second conductor, and the second resistor are arranged in series, where the second resistor is coupled to the second current path terminal of the first cascode amplifier, and where the second conductor is coupled to a third resistor, where the third resistor is coupled to the first control terminal of the third cascode amplifier.

Example 10. The electronic circuit of one of examples 1 to 9, where the first conductor is coupled to a current path terminal of a third transistor, where the third transistor has a control terminal coupled to a first bias voltage, where the first bias voltage is coupled to the third cascode amplifier, where a control terminal of a fourth transistor is coupled to the current path terminal of the third transistor, and where the fourth transistor is arranged between a first polarity power supply and the third transistor.

Example 11. The electronic circuit of one of examples 1 to 10, where the first conductor is coupled to an output terminal of an amplifier and to a first input terminal of the amplifier, where a second input terminal of the amplifier is coupled to the second current path terminal of the first cascode amplifier.

Example 12. The electronic circuit of one of examples 1 to 11, where the first transistor of each second component has a control terminal having controllable coupling to the second polarity power supply and to a first bias voltage, where the second transistor of each first component has a control terminal having controllable coupling to the first polarity power supply and to a second bias voltage.

Example 13. The electronic circuit of one of examples 1 to 12, where the first transistor of each second component is coupled between the first current path terminal of the first cascode amplifier and a conductor, and the second transistor of each second component is coupled between the first current path terminal of the third cascode amplifier and the conductor, where the conductor is coupled to the second current path terminal of the second cascode amplifier.

Example 14. The electronic circuit of one of examples 1 to 13, further including: an additional controllable circuit coupled to the first current path terminal of the second cascode amplifier, to the first current path terminal of the fourth cascode amplifier, and to the second output terminal; and a gain control circuit coupled to the controllable circuit and to the additional controllable circuit, where the gain control circuit is configured to control the controllable circuit to adjust an amount of first current through the second current path terminal of the first cascode amplifier and to control the additional controllable circuit to adjust an amount of second current through the second current path terminal of the second cascode amplifier.

Example 15. The electronic circuit of one of examples 1 to 14, where the first cascode amplifier includes N type metal oxide semiconductor (NMOS) transistors, where the second cascode amplifier includes NMOS transistors, where the third cascode amplifier includes Ptype metal oxide semiconductor (PMOS) transistors, and where the fourth cascode amplifier includes PMOS transistors.

Example 16. The electronic circuit of one of examples 1 to 15, further including: a first resistor coupled to the first control terminal of the third cascode amplifier and to the second current path terminal of the third cascode amplifier; and a second resistor coupled to the first control terminal of the fourth cascode amplifier and to the second current path terminal of the fourth cascode amplifier.

Example 17. The electronic circuit of one of examples 1 to 16, further including: an additional controllable circuit coupled to the first current path terminal of the second cascode amplifier and to the first current path terminal of the fourth cascode amplifier; a first resistor coupled to the first control terminal of the third cascode amplifier and to a common mode voltage of the controllable circuit; and a second resistor coupled to the first control terminal of the fourth cascode amplifier and to a common mode voltage of the additional controllable circuit.

Example 18. The electronic circuit of one of examples 1 to 17, where the first control terminal of the third cascode amplifier is coupled to the first control terminal of the first cascode amplifier via a third capacitor.

Example 19. An electronic circuit including: a first cascode amplifier having an output terminal; a second cascode amplifier having an output terminal, a third cascode amplifier having an output terminal, where the output terminal of the first cascode amplifier is coupled to the output terminal of the third cascode amplifier; a fourth cascode amplifier having an output terminal, where the output terminal of the fourth cascode amplifier is coupled to the output terminal of the second cascode amplifier; a first controllable circuit coupled to the first and third cascode amplifiers and configured to adjust a first amount of current at the output terminal of the first cascode amplifier; a second controllable circuit coupled to the second and fourth cascode amplifiers and configured to adjust a second amount of current at the output terminal of the second cascode amplifier; and a gain control circuit coupled to the first controllable circuit and to the second controllable circuit, the gain control circuit configured to adjust a gain at the output terminals of the first cascode amplifier, the second cascode amplifier, the third cascode amplifier, and the fourth cascode amplifier by applying control signals to the first controllable circuit and to the second controllable circuit.

Example 20. The electronic circuit of example 19, further including: a set of first components, each first component having a first transistor coupled between a current path terminal of the first cascode amplifier and the output terminal of the first cascode amplifier, and a second transistor coupled between a current path terminal of the third cascode amplifier and the output terminal of the third cascode amplifier; and a set of second components, each second component having a first transistor coupled between a current path terminal of the second cascode amplifier and the output terminal of the second cascode amplifier, and a second transistor coupled between a current path terminal of the fourth cascode amplifier and the output terminal of the fourth cascode amplifier.

Example 21. The circuit of one of examples 19 or 20, further including: a set of third components, each third component having a first transistor coupled between the current path terminal of the first cascode amplifier and a first power supply terminal, and a second transistor arranged between the current path terminal of the third cascode amplifier and a second power supply terminal; and a set of fourth components, each fourth component having a first transistor arranged between the current path terminal of the second cascode amplifier and the first power supply terminal, and a second transistor arranged between the current path terminal of the fourth cascode amplifier and the second power supply terminal.

Example 22. The electronic circuit of one of examples 19 to 21, where the gain control circuit is configured to: turn on a quantity (A) of the first and second transistors of the first and second components; and turn on a quantity (B) of the first and second transistors of the third and fourth components to achieve a gain setting of a low noise trans-impedance amplifier (LNTA) that includes the first, second, third, and fourth cascode amplifiers.

Example 23. The electronic circuit of one of examples 19 to 22, where the gain control circuit is configured to keep a quantity (X) constant across a plurality of gain settings of the LNTA, where A+1+B=X.

Example 24. The electronic circuit of one of examples 19 to 23, where the gain control circuit is configured to select A across a plurality of gain settings so that A+1−B is a power of two.

Example 25. The electronic circuit of one of examples 19 to 24, further including: a set of first components, each first component having a first transistor coupled between a current path terminal of the first cascode amplifier and the output terminal of the first cascode amplifier, and a second transistor coupled between a current path terminal of the third cascode amplifier and the output terminal of the third cascode amplifier; a set of second components, each second component having a first transistor coupled between a current path terminal of the second cascode amplifier and the output terminal of the second cascode amplifier, and a second transistor coupled between a current path terminal of the fourth cascode amplifier and the output terminal of the fourth cascode amplifier; a set of third components, each third component having a first transistor coupled between the current path terminal of the first cascode amplifier and a first conductor, and a second transistor coupled between the current path terminal of the third cascode amplifier and the first conductor; and a set of fourth components, each fourth component having a first transistor coupled between the current path terminal of the second cascode amplifier and a second conductor, and a second transistor coupled between the current path terminal of the fourth cascode amplifier and the second conductor.

Example 26. The electronic circuit of one of examples 19 to 25, further including: a first bias circuit configured to provide a first bias voltage to the first conductor; and a second bias circuit configured to provide a second bias voltage to the second conductor.

Example 27. The electronic circuit of one of examples 19 to 26, where the gain control circuit is configured to: turn on a quantity (A) of the first and second transistors of the first and second components; and turn on a quantity (B) of the first and second transistors of the third and fourth components to achieve a gain setting of a low noise trans-impedance amplifier (LNTA) that includes the first, second, third, and fourth cascode amplifiers.

Example 28. The electronic circuit of one of examples 19 to 27, where the gain control circuit is configured to keep a quantity (X) constant across a plurality of gain settings, where A+1+B=X.

Example 29. The electronic circuit of one of examples 19 to 28, where the gain control circuit is configured to select N across a plurality of gain settings so that A+1 is a power of two.

Example 30. The electronic circuit of one of examples 19 to 29, further including: a set of first components, each first component having a first transistor coupled between a current path terminal of the first cascode amplifier and the output terminal of the first cascode amplifier, and a second transistor arranged between a current path terminal of the third cascode amplifier and the output terminal of the third cascode amplifier; a set of second components, each second component having a first transistor coupled between a current path terminal of the second cascode amplifier and the output terminal of the second cascode amplifier, and a second transistor coupled between a current path terminal of the fourth cascode amplifier and the output terminal of the fourth cascode amplifier; a set of third components, each third component having a first transistor coupled between the current path terminal of the first cascode amplifier and a first conductor, and a second transistor arranged between the current path terminal of the third cascode amplifier and the first conductor; and a set of fourth components, each fourth component having a first transistor coupled between the current path terminal of the second cascode amplifier and a second conductor, and a second transistor arranged between the current path terminal of the fourth cascode amplifier and the second conductor.

Example 31. The electronic circuit of one of examples 19 to 30, where: the first conductor is coupled to a first resistor, a third conductor, and a second resistor, where the first resistor, the third conductor, and the second resistor are arranged in series, where the second resistor is coupled to the output terminal of the first cascode amplifier, and where the third conductor is coupled to a third resistor, where the third resistor is coupled to a control terminal of the third cascode amplifier; and the second conductor is coupled to a fourth resistor, a fourth conductor, and a fifth resistor, where the fourth resistor, the fourth conductor, and the fifth resistor are arranged in series, where the fifth resistor is coupled to the output terminal of the second cascode amplifier, and where the fourth conductor is coupled to a sixth resistor, where the sixth resistor is coupled to a control terminal of the fourth cascode amplifier.

Example 32. The electronic circuit of one of examples 19 to 31, further including: a first bias circuit configured to provide a first bias voltage to the first conductor; and a second bias circuit configured to provide a second bias voltage to the second conductor.

Example 33. The electronic circuit of one of examples 19 to 32, where the gain control circuit is configured to: turn on a quantity (A) of the first and second transistors of the first and second components; and turn on a quantity (B) of the first and second transistors of the third and fourth components to achieve a gain setting of a low noise trans-impedance amplifier (LNTA) that includes the first, second, third, and fourth cascode amplifiers.

Example 34. The electronic circuit of one of examples 19 to 33, where the gain control circuit is configured to keep a quantity (X) constant across a plurality of gain settings, where A+1+B=X.

Example 35. The electronic circuit of one of examples 19 to 34, where the gain control circuit is configured to select N across a plurality of gain settings so that A+1−B is a power of two.

Example 36. The electronic circuit of one of examples 19 to 35, further including: a set of first components, each first component having a first transistor coupled between a current path terminal of the first cascode amplifier and the output terminal of the first cascode amplifier, and a second transistor coupled between a current path terminal of the third cascode amplifier and the output terminal of the third cascode amplifier; a set of second components, each second component having a first transistor coupled between a current path terminal of the second cascode amplifier and the output terminal of the second cascode amplifier, and a second transistor coupled between a current path terminal of the fourth cascode amplifier and the output terminal of the fourth cascode amplifier; a set of third components, each third component having a first transistor coupled between the current path terminal of the first cascode amplifier and a first conductor, and a second transistor coupled between the current path terminal of the third cascode amplifier and the first conductor; and a set of fourth components, each fourth component having a first transistor coupled between the current path terminal of the second cascode amplifier and a second conductor, and a second transistor coupled between the current path terminal of the fourth cascode amplifier and the second conductor, where the first conductor is connected to the output terminal of the second cascode amplifier, and where the second conductor is connected to the output terminal of the first cascode amplifier.

Example 37. The electronic circuit of one of examples 19 to 36, where the gain control circuit is configured to: turn on a quantity (A) of the first and second transistors of the first and second components; and turn on a quantity (B) of the first and second transistors of the third and fourth components to achieve a gain setting of a low noise trans-impedance amplifier (LNTA) that includes the first, second, third, and fourth cascode amplifiers.

Example 38. The electronic circuit of one of examples 19 to 37, where the gain control circuit is configured to keep a quantity (X) constant across a plurality of gain settings, where A+1+B=X.

Example 39. The electronic circuit of one of examples 19 to 38, where the gain control circuit is configured to select N across a plurality of gain settings so that (A+1)−B is a power of two.

Example 40. A device including: a low noise trans-impedance amplifier (LNTA) including: a first cascode amplifier having an output terminal; a second cascode amplifier having an output terminal, a third cascode amplifier having an output terminal, where the output terminal of the first cascode amplifier is coupled to the output terminal of the third cascode amplifier; a fourth cascode amplifier having an output terminal, where the output terminal of the fourth cascode amplifier is coupled to the output terminal of the second cascode amplifier; a first controllable circuit coupled to the first and third cascode amplifiers and configured to adjust a first amount of current at the output terminal of the first cascode amplifier; and a second controllable circuit coupled to the second and fourth cascode amplifiers and configured to adjust a second amount of current at the output terminal of the second cascode amplifier; and a gain control circuit, coupled to the first controllable circuit and to the second controllable circuit, and configured to affect a gain of the LNTA by applying control signals to the first controllable circuit and to the second controllable circuit.

Example 41. The device of example 40, where the device is implemented as an integrated circuit.

Example 42. The device of one of examples 40 or 41, further including: a first mixer having a first differential input and a second differential input; and a second mixer having a first differential input and a second differential input, where the output terminal of the second cascode amplifier and the output terminal of the fourth cascode amplifier are coupled to the first differential input of the first mixer, and where the output terminal of the first cascode amplifier and the output terminal of the third cascode amplifier are coupled to the second differential input of the first mixer, and where the output terminal of the second cascode amplifier and the output terminal of the fourth cascode amplifier are coupled to the first differential input of the second mixer, and where the output terminal of the first cascode amplifier and the output terminal of the third cascode amplifier are coupled to the second differential input of the second mixer.

Example 43. The device of one of examples 40 to 42, further including: a first adjustable attenuator coupled between the LNTA and the first mixer; and a second adjustable attenuator coupled between the LNTA and the second mixer.

Example 44. The device of one of examples 40 to 43, further including: a first intermediate frequency amplifier coupled to an output of the first mixer; a second intermediate frequency amplifier coupled to an output of the second mixer; a first variable gain amplifier coupled to an output of the first intermediate frequency amplifier; and a second variable gain amplifier coupled to an output of the second intermediate frequency amplifier.

Example 45. The device of one of examples 40 to 44, further including: an analog-to-digital converter circuit coupled to an output of the first variable gain amplifier and coupled to an output of the second variable gain amplifier.

Example 46. The device of one of examples 40 to 45, where the analog-to-digital converter circuit includes a first analog-to-digital converter coupled to the output of the first variable gain amplifier and a second analog-to-digital converter coupled to the output of the second variable gain amplifier.

Example 47. The device of one of examples 40 to 46, where the LNTA is implemented in a receive path of the device, the device further including: a digital processing circuit; and a transmit path, where the receive path in the transmit path are coupled to the digital processing circuit.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. An electronic circuit comprising:
first and second output terminals;
an input terminal;
a first cascode amplifier having first and second control terminals and first and second current path terminals, wherein the first control terminal of the first cascode amplifier is coupled to the input terminal, and wherein the second current path terminal of the first cascode amplifier is coupled to the first output terminal;
a second cascode amplifier having first and second control terminals and first and second current path terminals, wherein the first control terminal of the second cascode amplifier is coupled to the first current path terminal of the first cascode amplifier via a first capacitor;
a third cascode amplifier having first and second control terminals and first and second current path terminals, wherein the second current path terminal of the third cascode amplifier is coupled to the first output terminal, and wherein the second current path terminal of the third cascode amplifier is coupled to the second output terminal;
a fourth cascode amplifier having first and second control terminals and first and second current path terminals, wherein the first control terminal of the fourth cascode amplifier is coupled to the first current path terminal of the third cascode amplifier via a second capacitor, and wherein the second current path terminal of the fourth cascode amplifier is coupled to the second output terminal; and
a controllable circuit comprising:
a set of first components, each first component having a first transistor arranged between the first current path terminal of the first cascode amplifier and the second current path terminal of the first cascode amplifier and a second transistor arranged between the first current path terminal of the third cascode amplifier and the second current path terminal of the third cascode amplifier, and
a set of second components, each second component having a first transistor coupled to the first current path terminal of the first cascode amplifier, and a second transistor coupled to the first current path terminal of the third cascode amplifier.

2. The electronic circuit of claim 1, wherein the first transistor of each first component has a control terminal having controllable coupling to a first polarity power supply and to a first bias voltage, wherein the second transistor of each first component has a control terminal having controllable coupling to a second polarity power supply and to a second bias voltage.

3. The electronic circuit of claim 1, wherein the first transistor of each second component is coupled between the first current path terminal of the first cascode amplifier and a first polarity power supply, and the second transistor of each second component is coupled between the first current path terminal of the third cascode amplifier and a second polarity power supply.

4. The electronic circuit of claim 3, wherein the first transistor of each second component has a control terminal having controllable coupling to the second polarity power supply and to a first bias voltage, wherein the second transistor of each first component has a control terminal having controllable coupling to the first polarity power supply and to a second bias voltage.

5. The electronic circuit of claim 1, wherein the first transistor of each second component is coupled between the first current path terminal of the first cascode amplifier and a conductor, and the second transistor of each second component is coupled between the first current path terminal of the third cascode amplifier and the conductor.

6. The electronic circuit of claim 5, wherein the first transistor of each second component has a control terminal having controllable coupling to a first polarity power supply and to a first bias voltage, wherein the second transistor of each first component has a control terminal having controllable coupling to a second polarity power supply and to a second bias voltage.

7. The electronic circuit of claim 6, wherein the conductor is coupled to a current path terminal of a third transistor, wherein the third transistor has a control terminal coupled to the second bias voltage, wherein the first bias voltage is coupled to the first cascode amplifier, wherein a control terminal of a fourth transistor is coupled to the current path terminal of the third transistor, and wherein the fourth transistor is arranged between the second polarity power supply and the third transistor.

8. The electronic circuit of claim 6, wherein the conductor is coupled to an output terminal of an amplifier and to a first input terminal of the amplifier, wherein a second input terminal of the amplifier is coupled to the second current path terminal of the first cascode amplifier.

9. The electronic circuit of claim 1, wherein the first transistor of each second component is coupled between the first current path terminal of the first cascode amplifier and a first conductor and, the second transistor of each second component is coupled between the first current path terminal of the third cascode amplifier and the first conductor, wherein the first conductor is coupled to a first resistor, a second conductor, and a second resistor, wherein the first resistor, the second conductor, and the second resistor are arranged in series, wherein the second resistor is coupled to the second current path terminal of the first cascode amplifier, and wherein the second conductor is coupled to a third resistor, wherein the third resistor is coupled to the first control terminal of the third cascode amplifier.

10. The electronic circuit of claim 9, wherein the first conductor is coupled to a current path terminal of a third transistor, wherein the third transistor has a control terminal coupled to a first bias voltage, wherein the first bias voltage is coupled to the third cascode amplifier, wherein a control terminal of a fourth transistor is coupled to the current path terminal of the third transistor, and wherein the fourth transistor is arranged between a first polarity power supply and the third transistor.

11. The electronic circuit of claim 9, wherein the first conductor is coupled to an output terminal of an amplifier and to a first input terminal of the amplifier, wherein a second input terminal of the amplifier is coupled to the second current path terminal of the first cascode amplifier.

12. The electronic circuit of claim 9, wherein the first transistor of each second component has a control terminal having controllable coupling to a first polarity power supply and to a first bias voltage, wherein the second transistor of each first component has a control terminal having controllable coupling to a second polarity power supply and to a second bias voltage.

13. The electronic circuit of claim 1, wherein the first transistor of each second component is coupled between the first current path terminal of the first cascode amplifier and a conductor, and the second transistor of each second component is coupled between the first current path terminal of the third cascode amplifier and the conductor, wherein the conductor is coupled to the second current path terminal of the second cascode amplifier.

14. The electronic circuit of claim 1, further comprising:
an additional controllable circuit coupled to the first current path terminal of the second cascode amplifier, to the first current path terminal of the fourth cascode amplifier, and to the second output terminal; and
a gain control circuit coupled to the controllable circuit and to the additional controllable circuit, wherein the gain control circuit is configured to control the controllable circuit to adjust an amount of first current through the second current path terminal of the first cascode amplifier and to control the additional controllable circuit to adjust an amount of second current through the second current path terminal of the second cascode amplifier.

15. The electronic circuit of claim 1, wherein the first cascode amplifier comprises N type metal oxide semiconductor (NMOS) transistors, wherein the second cascode amplifier comprises NMOS transistors, wherein the third cascode amplifier comprises P type metal oxide semiconductor (PMOS) transistors, and wherein the fourth cascode amplifier comprises PMOS transistors.

16. The electronic circuit of claim 1, further comprising:
a first resistor coupled to the first control terminal of the third cascode amplifier and to the second current path terminal of the third cascode amplifier; and
a second resistor coupled to the first control terminal of the fourth cascode amplifier and to the second current path terminal of the fourth cascode amplifier.

17. The electronic circuit of claim 1, further comprising:
an additional controllable circuit coupled to the first current path terminal of the second cascode amplifier and to the first current path terminal of the fourth cascode amplifier;
a first resistor coupled to the first control terminal of the third cascode amplifier and to a common mode voltage of the controllable circuit; and
a second resistor coupled to the first control terminal of the fourth cascode amplifier and to a common mode voltage of the additional controllable circuit.

18. The electronic circuit of claim 1, wherein the first control terminal of the third cascode amplifier is coupled to the first control terminal of the first cascode amplifier via a third capacitor.

19. An electronic circuit comprising:
a first cascode amplifier having an output terminal;
a second cascode amplifier having an output terminal,
a third cascode amplifier having an output terminal, wherein the output terminal of the first cascode amplifier is coupled to the output terminal of the third cascode amplifier;
a fourth cascode amplifier having an output terminal, wherein the output terminal of the fourth cascode amplifier is coupled to the output terminal of the second cascode amplifier;
a first controllable circuit coupled to the first and third cascode amplifiers and configured to adjust a first amount of current at the output terminal of the first cascode amplifier;
a second controllable circuit coupled to the second and fourth cascode amplifiers and configured to adjust a second amount of current at the output terminal of the second cascode amplifier; and
a gain control circuit coupled to the first controllable circuit and to the second controllable circuit, the gain control circuit configured to adjust a gain at the output terminals of the first cascode amplifier, the second cascode amplifier, the third cascode amplifier, and the fourth cascode amplifier by applying control signals to the first controllable circuit and to the second controllable circuit.

20. A device comprising:
a low noise trans-impedance amplifier (LNTA) including:
a first cascode amplifier having an output terminal;
a second cascode amplifier having an output terminal,
a third cascode amplifier having an output terminal, wherein the output terminal of the first cascode amplifier is coupled to the output terminal of the third cascode amplifier;
a fourth cascode amplifier having an output terminal, wherein the output terminal of the fourth cascode amplifier is coupled to the output terminal of the second cascode amplifier;
a first controllable circuit coupled to the first and third cascode amplifiers and configured to adjust a first amount of current at the output terminal of the first cascode amplifier; and
a second controllable circuit coupled to the second and fourth cascode amplifiers and configured to adjust a second amount of current at the output terminal of the second cascode amplifier; and
a gain control circuit, coupled to the first controllable circuit and to the second controllable circuit, and configured to affect a gain of the LNTA by applying control signals to the first controllable circuit and to the second controllable circuit.

21. The device of claim 20, wherein the device is implemented as an integrated circuit.

22. The device of claim 20, further comprising:
a first mixer having a first differential input and a second differential input; and
a second mixer having a first differential input and a second differential input,
wherein the output terminal of the second cascode amplifier and the output terminal of the fourth cascode amplifier are coupled to the first differential input of the first mixer, and wherein the output terminal of the first cascode amplifier and the output terminal of the third cascode amplifier are coupled to the second differential input of the first mixer, and
wherein the output terminal of the second cascode amplifier and the output terminal of the fourth cascode amplifier are coupled to the first differential input of the second mixer, and wherein the output terminal of the first cascode amplifier and the output terminal of the third cascode amplifier are coupled to the second differential input of the second mixer.

23. The device of claim 22, further comprising:
a first adjustable attenuator coupled between the LNTA and the first mixer; and
a second adjustable attenuator coupled between the LNTA and the second mixer.

24. The device of claim 23, further comprising:
a first intermediate frequency amplifier coupled to an output of the first mixer;
a second intermediate frequency amplifier coupled to an output of the second mixer;
a first variable gain amplifier coupled to an output of the first intermediate frequency amplifier; and
a second variable gain amplifier coupled to an output of the second intermediate frequency amplifier.

25. The device of claim 24, further comprising:
an analog-to-digital converter circuit coupled to an output of the first variable gain amplifier and coupled to an output of the second variable gain amplifier.

26. The device of claim 25, wherein the analog-to-digital converter circuit comprises a first analog-to-digital converter coupled to the output of the first variable gain amplifier and a second analog-to-digital converter coupled to the output of the second variable gain amplifier.

27. The device of claim 26, wherein the LNTA is implemented in a receive path of the device, the device further comprising:
a digital processing circuit; and
a transmit path, wherein the receive path in the transmit path are coupled to the digital processing circuit.
